(19) United States
(12) Patent Application Publication
(10) Pub. No.: US 2026/0234441 A1
(43) Pub. Date: Aug. 13, 2026

(54) RESIN COMPOSITION, METHOD FOR MANUFACTURING ELECTRONIC APPARATUS, AND ELECTRONIC APPARATUS

(71) Applicant: Samsung Display Co., Ltd., Yongin-si (KR)

(72) Inventor: Koki Ikuta, Kanagawa (JP)

(73) Assignee: Samsung Display Co., Ltd., Yongin-si (KR)

(21) Appl. No.: 19/461,048

(22) Filed: Jan. 27, 2026

(30) Foreign Application Priority Data
Feb. 7, 2025 (JP) 2025-019116

(51) Int. Cl. C09J 4/06; C09J 5/00; C09J 133/06; H05K 5/03

(52) U.S. Cl. CPC C09J 4/06; C09J 5/00; C09J 133/066; H05K 5/03

(57) ABSTRACT

The resin composition of an embodiment may include at least one monofunctional (meth)acrylate compound, at least one photopolymerization initiator, and a dendritic (meth)acrylate copolymer having at least one (meth)acrylate group at at least one terminal, wherein a shear viscosity may be about 50 mPa·s or less as measured by a JISZ8803 method at about 30° C. Accordingly, the resin composition of an embodiment may exhibit excellent processability when photocured in the air and excellent adhesive strength after curing.

### CROSS-REFERENCE TO RELATED APPLICATIONS

This application claims priority under 35 U.S.C. § 119 of Japanese Patent Application No. JP 2025-019116, filed on Feb. 7, 2025, the entire contents of which are hereby incorporated by reference.

### BACKGROUND

The present disclosure relates to a resin composition including a dendritic (meth)acrylate copolymer, a method for manufacturing an electronic apparatus including providing the resin composition, and an electronic apparatus.

Various electronic apparatuses for use in multimedia apparatuses such as televisions, mobile phones, tablet computers, navigation systems, and game consoles, are being developed. The electronic apparatuses include various components constituting the electronic apparatuses and may include display panels that generate images. Adhesive members are disposed between the components constituting the electronic apparatuses. The adhesive members may be formed by providing a resin composition, and the adhesive members included in the electronic apparatuses are required to have the characteristics of stably bonding the components of the electronic apparatuses, while not degrading display quality.

### SUMMARY

An object of the present disclosure is to provide a resin composition exhibiting excellent discharge properties, excellent processability during curing, and high adhesive properties after curing.

Another object of the present disclosure is to provide a method for manufacturing an electronic apparatus that exhibits excellent processability.

Another object of the present disclosure is to provide an electronic apparatus that exhibits excellent reliability.

An embodiment provides a resin composition including at least one monofunctional (meth)acrylate compound, at least one photopolymerization initiator, and a dendritic (meth)acrylate copolymer having at least one (meth)acrylate group at at least one terminal, wherein a shear viscosity is about 50 mPa·s or less as measured by a JISZ8803 method at about 30° C. The term “about” means±5%, ±10%, ±20%, and ±30% for purposes of this specification.

A weight average molecular weight of the dendritic (meth)acrylate copolymer may be about 3,000 or more.

The dendritic (meth)acrylate copolymer may be synthesized using a (meth)acrylate monomer and a radical polymerization initiator.

The (meth)acrylate monomer may include at least one among methyl methacrylate (MMA) and isobornyl methacrylate (IBXMA).

The resin composition may further include at least one urethane (meth)acrylate having a weight average molecular weight of about 4,000 or more and about 50,000 or less, and a weight of the urethane (meth)acrylate may be about 1 wt % or more and about 20 wt % or less based on 100 wt % of a total weight of the resin composition.

The resin composition may have, after photocuring in the air, a 180° peel strength against a glass substrate at about 25° C. of about 1500 gf/25 mm or more.

The resin composition may have, after photocuring in the air, a 180° peel strength against a glass substrate under conditions of about 85° C. and about 85% relative humidity of about 200 gf/25 mm or more.

The resin composition may be provided by an inkjet printing method or a dispensing method.

An embodiment provides a method for manufacturing an electronic apparatus, the method including preparing a display module, providing a window on the display module, and providing an adhesive member on the display module or the window prior to the providing of the window, wherein the providing of the adhesive member includes providing a resin composition having a shear viscosity of about 50 mPa·s or less as measured by a JISZ8803 method at about 30° C. on the display module or the window, and irradiating the provided resin composition with light in the air to form the adhesive member, wherein the resin composition includes at least one monofunctional (meth)acrylate compound, at least one photopolymerization initiator, and a dendritic (meth)acrylate copolymer having at least one (meth)acrylate group at at least one terminal, and the light includes UVA and UVV and has an accumulated illuminance of about 900 mW and an accumulated light quantity of about 1800 mJ/cm².

The adhesive member used in the method may have a 180° peel strength of about 1500 gf/25 mm or more against a glass substrate at about 25° C.

The adhesive member used in the method may have a 180° peel strength of about 200 gf/25 mm or more against a glass substrate under conditions of about 85° C. and about 85% relative humidity.

A weight average molecular weight of the dendritic (meth)acrylate copolymer used in the method may be about 3,000 or more.

The dendritic (meth)acrylate copolymer used in the method may be synthesized using a (meth)acrylate monomer and a radical polymerization initiator.

The resin composition used in the method may further include at least one urethane (meth)acrylate having a weight average molecular weight of about 4,000 or more and about 50,000 or less, and a weight of the urethane (meth)acrylate may be about 1 wt % or more and about 20 wt % or less based on 100 wt % of a total weight of the resin composition.

An embodiment provides an electronic apparatus including a display module, a window disposed on the display module, and an adhesive member disposed between the display module and the window, wherein the adhesive member includes a polymer obtained from a resin composition including at least one monofunctional (meth)acrylate compound, at least one photopolymerization initiator, and a dendritic (meth)acrylate copolymer having at least one (meth)acrylate group at at least one terminal, and the resin composition has a shear viscosity of about 50 mPa·s or less as measured by a JISZ8803 method at about 30° C.

The adhesive member in the electronic apparatus may have a 180° peel strength of about 1500 gf/25 mm or more against a glass substrate at about 25° C.

The adhesive member in the electronic apparatus may have a 180° peel strength of about 200 gf/25 mm or more against a glass substrate under conditions of about 85° C. and about 85% relative humidity.

The electronic apparatus may further include a light control layer disposed between the adhesive member and the window and an optical adhesive layer disposed between the light control layer and the window, and the optical adhesive layer may include a polymer obtained from the resin composition.

The display module may further include a display panel and an input detection part disposed between the display panel and the window, and the adhesive member may be disposed between the display panel and the input detection part or between the input detection part and the window.

The electronic apparatus may further include at least one among a processor, a memory and a power module.

### BRIEF DESCRIPTION OF DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a perspective view showing an electronic apparatus of an embodiment;

FIG. 2 is a block diagram of an electronic apparatus according to an embodiment;

FIG. 3 shows schematic diagrams showing electronic apparatuses according to various embodiments;

FIG. 4 is an exploded perspective view showing an electronic apparatus of an embodiment;

FIG. 5 is a cross-sectional view showing a portion corresponding to line I-I′ in FIG. 1;

FIG. 6 is a cross-sectional view showing a portion of an electronic apparatus according to an embodiment;

FIG. 7A is a flowchart showing a method for manufacturing an electronic apparatus of an embodiment;

FIG. 7B is a flowchart showing part of a method for manufacturing an electronic apparatus of an embodiment;

FIG. 8A is a diagram schematically showing a manufacturing step of an electronic apparatus of an embodiment;

FIG. 8B is a diagram schematically showing a manufacturing step of an electronic apparatus of an embodiment;

FIG. 8C is a diagram schematically showing a manufacturing step of an electronic apparatus of an embodiment;

FIG. 9A is a diagram schematically showing a manufacturing step of an electronic apparatus of an embodiment;

FIG. 9B is a diagram schematically showing a manufacturing step of an electronic apparatus of an embodiment;

FIG. 9C is a diagram schematically showing a manufacturing step of an electronic apparatus of an embodiment;

FIG. 10A is a diagram schematically showing a manufacturing step of an electronic apparatus of an embodiment;

FIG. 10B is a diagram schematically showing a manufacturing step of an electronic apparatus of an embodiment;

FIG. 10C is a diagram schematically showing a manufacturing step of an electronic apparatus of an embodiment;

FIG. 10D is a diagram schematically showing a manufacturing step of an electronic apparatus of an embodiment;

FIG. 11 is a cross-sectional view showing an electronic apparatus according to an embodiment;

FIG. 12 is a cross-sectional view showing an electronic apparatus according to an embodiment; and

FIG. 13 is a diagram showing the interior of a vehicle in which electronic apparatuses according to embodiments are disposed.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the present disclosure. Similarly, a second element, component, region, layer or section could be termed a first element, component, region, layer or section. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises”, “includes”, “has”, “comprising”, “including”, and “having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

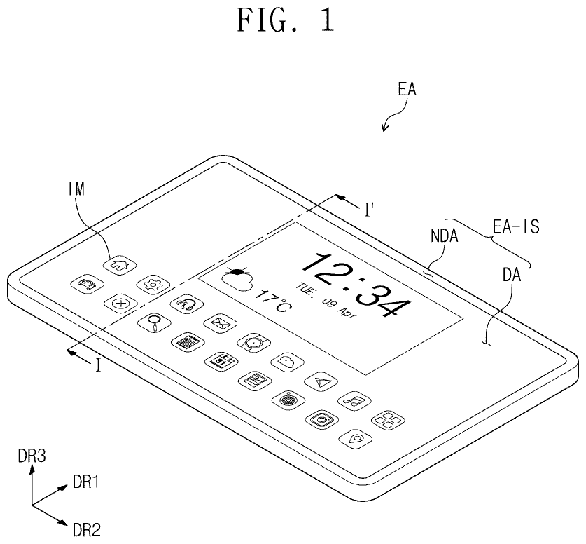

Hereinafter, embodiments of the present disclosure will be described with reference to the drawings. FIG. 1 is a perspective view showing an electronic apparatus of an embodiment.

An electronic apparatus EA of an embodiment illustrated in FIG. 1 may be an apparatus activated by an electrical signal. For example, the electronic apparatus EA may be a personal computer, a laptop computer, a personal digital terminal, a game console, a portable electronic device, a television, a monitor, an outdoor billboard, a car navigation system, or a wearable apparatus, but an embodiment of the present disclosure is not limited thereto. FIG. 1 illustrates an embodiment of the electronic apparatus EA as a portable electronic device.

The electronic apparatus EA may provide an image IM to a user through a display surface EA-IS. The display surface EA-IS may be parallel to a plane defined by a first direction axis DR1 and a second direction axis DR2. The electronic apparatus EA may display the image IM along a third direction axis DR3. The image IM may include a dynamic image and/or a static image. Although FIG. 1 illustrates an electronic apparatus EA having a flat display surface EA-IS, an embodiment of the present disclosure is not limited thereto. For example, the electronic apparatus EA may include a curved display surface or a three-dimensional display surface. The three-dimensional display surface may include multiple display areas pointing in different directions.

The directions indicated by the first to third direction axes DR1, DR2 and DR3 described herein are relative concepts and may be converted into other directions. In addition, the directions indicated by the first to third direction axes DR1, DR2 and DR3 may be described as the first to third directions, and the same reference numerals may be used.

In this specification, the first direction axis DR1 and the second direction axis DR2 are orthogonal to each other, and the third direction axis DR3 may be a normal direction to the plane defined by the first direction axis DR1 and the second direction axis DR2. The thickness direction of the electronic apparatus EA may be parallel to the third direction axis DR3. The thickness direction of the electronic apparatus EA may use the same drawing symbol as the third direction axis DR3. The front surface (or top) and the back surface (or bottom) may be opposite each other along the third direction axis DR3, and the normal directions of each of the front surface (or top) and the back surface (or bottom) may be parallel to the third direction axis DR3. The front surface (or top) refers to a surface adjacent to the display surface EA-IS, and the back surface (or bottom) refers to a surface spaced from the display surface EA-IS. The upper side refers to a direction approaching the display surface EA-IS, and the lower side refers to a direction away from the display surface EA-IS.

In this specification, a cross-section refers to a surface parallel to the thickness direction DR3. A plane is a surface that is perpendicular to the thickness direction DR3 and parallel to the plane defined by the first direction axis DR1 and the second direction axis DR2.

In this specification, overlapping of a component with another component means overlapping on a plane. In addition, overlapping of a component with another component is not limited to cases where the component and another component have the same area and shape but includes cases where the component and another component have different areas and/or different shapes.

The electronic apparatus EA may detect external input applied from outside. External input may include various forms of input provided from outside the electronic apparatus EA. For example, external input may include contact by a part of the user's body, such as a hand, as well as external input (for example, hovering) applied from within proximity to the electronic apparatus EA or a certain distance away. Furthermore, external input may take various forms such as force, pressure, temperature and light.

The display surface EA-IS may include a display area DA and a non-display area NDA. The electronic apparatus EA may display an image IM through the display area DA.

The display area DA may be an area activated by an electrical signal. The display area DA may be an area where an image IM is displayed and where various types of external input may be detected.

The display area DA may include the plane defined by the first direction axis DR1 and the second direction axis DR2. Although not illustrated, the display area DA may also include a curved surface bent from at least one side of the plane defined by the first direction axis DR1 and the second direction axis DR2. For example, the display area DA may further include four curved surfaces each bent from at least two sides, for example, four sides, of the plane defined by the first direction axis DR1 and the second direction axis DR2.

The electronic apparatus EA of an embodiment may be flexible. “Flexible” refers to a property capable of being bent and may include structures ranging from a completely foldable structure to a structure capable of being bent to a degree of several nanometers. For example, the electronic apparatus EA may be a rigid device. Differently, the electronic apparatus EA may be a foldable device.

The non-display area NDA may have a color. The non-display area NDA may be an area adjacent to the display area DA. The non-display area NDA may surround the display area DA. Accordingly, the shape of the display area DA may be substantially defined by the non-display area NDA. However, FIG. 1 is merely an embodiment, and the non-display area NDA may be disposed adjacent to only one side of the display area DA or may be omitted. The display area DA may be provided in various shapes and is not limited to any one embodiment.

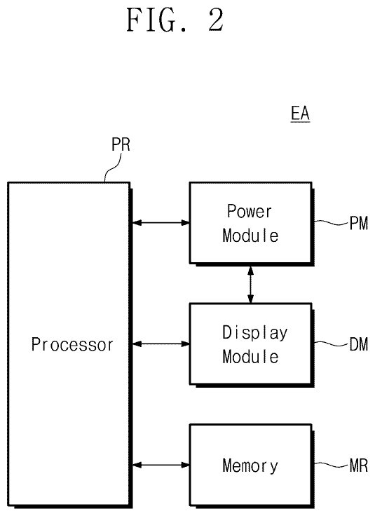

FIG. 2 is a block diagram of an electronic apparatus according to an embodiment. Referring to FIG. 2, an electronic apparatus EA according to an embodiment may include a display module DM, a processor PR, a memory MR, and a power module PM. In this specification, the electronic apparatus EA may be a display apparatus or may include a display apparatus. The display apparatus may include a display module DM.

The processor PR may include at least one of a central processing unit (CPU), an application processor (AP), a graphics processing unit (GPU), a communication processor (CP), an image signal processor (ISP), and a controller.

The memory MR may store data information necessary for the operation of the processor PR or the display module DM. When the processor PR executes an application stored in the memory MR, image data signals and/or input control signals are transmitted to the display module DM, and the display module DM may process the received signals and output image information through a display screen.

The power module PM may include a power supply module such as a power adapter or battery, and a power conversion module that converts the power supplied by the power supply module to generate power necessary for the operation of the electronic apparatus EA.

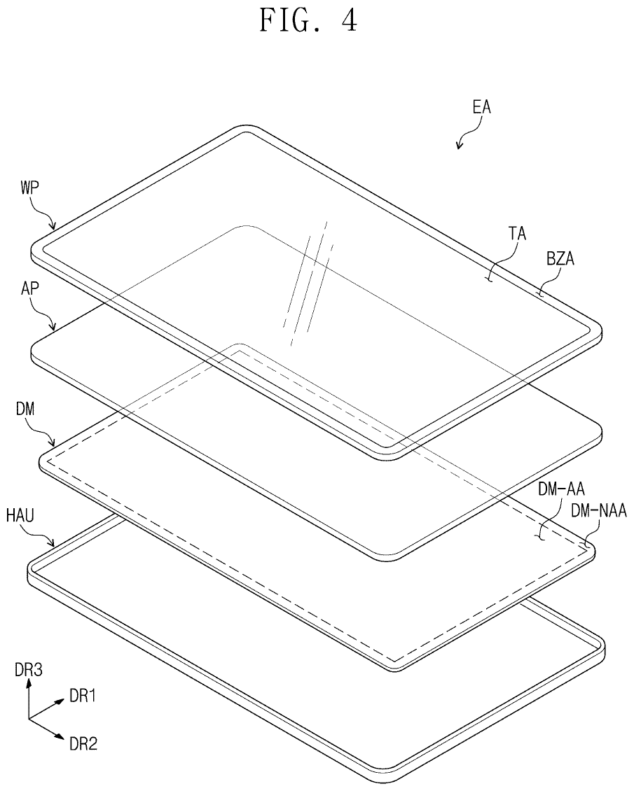

At least one of the components of the electronic apparatus EA may be included in a display module DM (FIG. 4) according to an embodiment. In addition, among the components of the electronic apparatus EA, some of the individual modules functionally included within a single module may be included within the display apparatus, while others may be provided separately from the display apparatus. For example, the display apparatus may include the display module DM, and the processor PR, memory MR and power module PM may be provided as separate components within the electronic apparatus EA rather than the display apparatus.

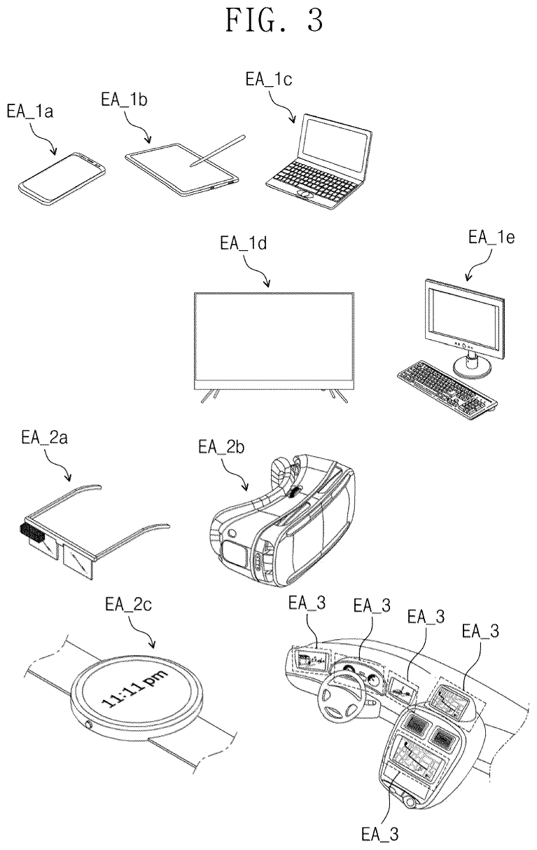

FIG. 3 is a schematic diagram showing electronic apparatuses according to various embodiments. Referring to FIG. 3, an electronic apparatus including a display module DM (FIG. 4) according to an embodiment may include not only image display electronic apparatuses such as a smart phone EA_1a, a tablet PC EA_1b, a laptop EA_1c, a TV EA_1d, and a desk monitor (EA_1e), but also wearable electronic apparatuses including display modules such as smart glasses EA_2a, a head-mounted display EA_2b, and a smart watch EA_2c, and a vehicle electronic apparatus EA_3 including display modules such as an instrument panel, a center fascia, a center information display (CID) disposed on a dashboard and a room mirror display of a vehicle.

FIG. 4 is an exploded perspective view showing an electronic apparatus according to an embodiment. Referring to FIG. 4, the electronic apparatus EA may include a display module DM, a window WP disposed on the display module DM, and an adhesive member AP disposed between the display module DM and the window WP. In addition, the electronic apparatus EA may further include a housing HAU.

In the electronic apparatus EA shown in FIG. 4, the window WP and the housing HAU may be combined to form the exterior of the electronic apparatus EA. The housing HAU may be disposed below the display module DM. The housing HAU may include a material with relatively high rigidity. For example, the housing HAU may include a plurality of frames and/or plates composed of glass, plastic or metal. The housing HAU may provide an accommodation space. The display module DM may be accommodated within the accommodation space and protected from external impact.

The display module DM may be activated in response to an electrical signal and provide an image IM (FIG. 1). The display module DM may be activated to display an image IM (FIG. 1) on the display area DA (FIG. 1) of the electronic apparatus EA. The display module DM may define an active area DM-AA and a peripheral area DM-NAA.

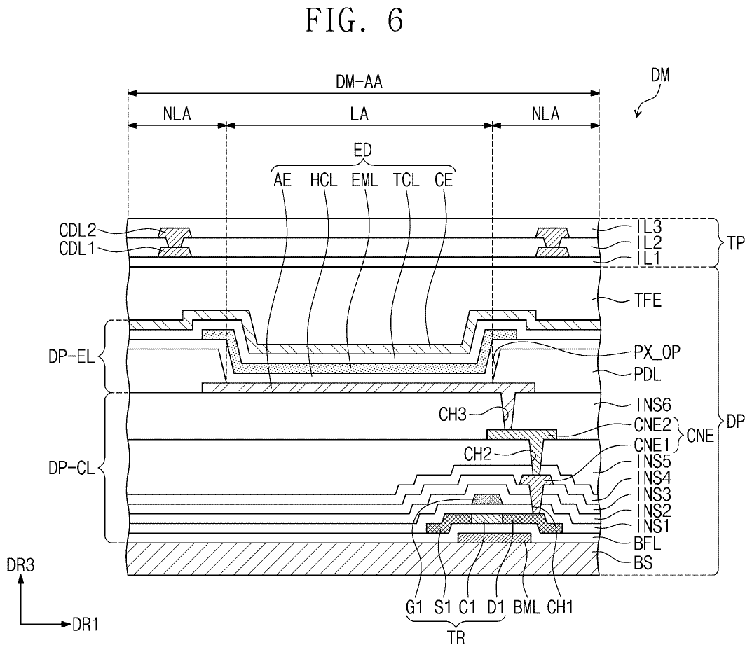

The active area DM-AA may be an area activated by an electrical signal. A pixel (not shown) may be disposed in the active area DM-AA. The pixel may include a transistor TR and a light emitting element ED (FIG. 6). The peripheral area DM-NAA may be an area positioned adjacent to at least one side of the active area DM-AA. Circuits or wiring for driving the active area DM-AA may be positioned in the peripheral area DM-NAA.

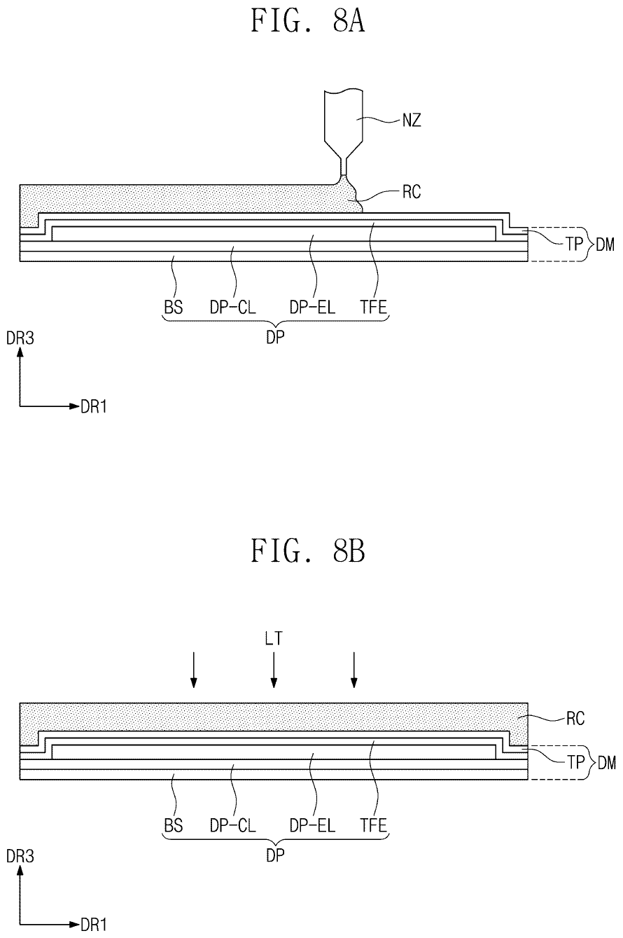

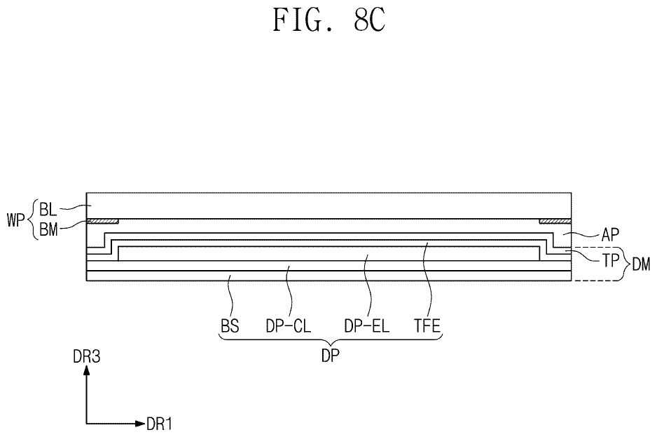

The display module DM and the window WP may be joined by an adhesive member AP. In an embodiment, the adhesive member AP may include a polymer obtained from a resin composition RC (FIGS. 8A, 9A and 10A). The adhesive member AP may be formed by photocuring the resin composition RC (FIGS. 8A, 9A and 10A). The adhesive member AP may be formed from the resin composition RC (FIGS. 8A, 9A and 10A) of an embodiment and exhibit excellent adhesive strength. In an embodiment, an electronic apparatus EA including the adhesive member AP may exhibit excellent reliability.

A window WP may be disposed on the adhesive member AP. The window WP may cover the entire outer surface of the electronic apparatus EA. The window WP may include a transparent area TA and a bezel area BZA. The front surface of the window WP, including the transparent area TA and the bezel area BZA, may correspond to the front surface of the electronic apparatus EA. The transparent area TA may correspond to the display area DA of the electronic apparatus EA illustrated in FIG. 1, and the bezel area BZA may correspond to the non-display area NDA of the electronic apparatus EA illustrated in FIG. 1.

The transparent area TA may be an optically transparent area. The bezel area BZA may have a relatively low light transmittance compared to the transparent area TA. The bezel area BZA may have a color. The bezel area BZA may be adjacent to the transparent area TA and may surround the transparent area TA. The bezel area BZA may define the shape of the transparent area TA. However, an embodiment of the present disclosure is not limited to the illustration, and the bezel area BZA may be disposed adjacent to only one side of the transparent area TA, or a portion thereof may be omitted.

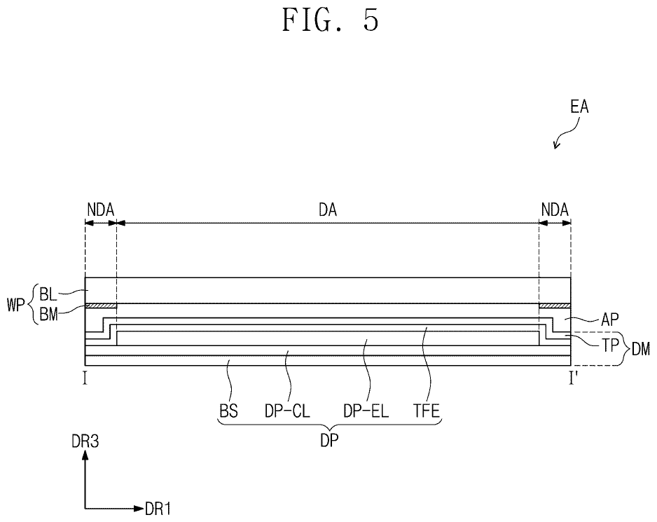

FIG. 5 is a cross-sectional view showing a portion corresponding to line I-I′ in FIG. 1. FIG. 5 may be a cross-sectional view schematically showing an electronic apparatus EA according to an embodiment.

Referring to FIG. 5, the display module DM may include a display panel DP and an input detection part TP disposed on the display panel DP. The display panel DP may be a configuration that actually generates an image. The display panel DP may include a base substrate BS, a circuit layer DP-CL disposed on the base substrate BS, a display element layer DP-EL disposed on the circuit layer DP-CL, and an encapsulation layer TFE covering the display element layer DP-EL. The window WP may be disposed on the display panel DP. The adhesive member AP may be disposed between the display panel DP and the window WP. The adhesive member AP may be disposed between the input detection part TP disposed on the display panel DP and the window WP.

The adhesive member AP according to an embodiment may have a 180° peel strength of about 1500 gf/25 mm or more and about 3000 gf/25 mm or less against a glass substrate at about 25° C. The adhesive member AP formed from the resin composition RC (FIGS. 8A, 9A and 10A) according to an embodiment may exhibit a high 180° peel strength of about 1500 gf/25 mm or more. An adhesive member with a 180° peel strength of less than about 1500 gf/25 mm against a glass substrate at about 25° C. has low adhesive strength and peels off from adjacent components of the display apparatus (for example, a display module DM, a window WP, or the like). Differently, the adhesive member AP of an embodiment having a 180° peel strength of about 1500 gf/25 mm or more against a glass substrate at about 25° C. exhibits excellent adhesive strength and may stably bond components of the electronic apparatus EA (for example, a display module DM, a window WP, or the like).

According to an embodiment, the adhesive member AP may have a 180° peel strength of about 200 gf/25 mm or more and 500 gf/25 mm or less against a glass substrate at about 85° C. and about 85% relative humidity. The about 85° C. and about 85% relative humidity may be considered a high-temperature and high-humidity environment. The adhesive member AP formed from the resin composition RC (FIGS. 8A, 9A and 10A) according to an embodiment may exhibit a high 180° peel strength of about 200 gf/25 mm or more under conditions of about 85° C. and about 85% relative humidity. An adhesive member having a 180° peel strength of less than about 200 gf/25 mm with respect to a glass substrate under conditions of about 85° C. and about 85% relative humidity has low adhesive strength and is peeled off from adjacent components of a display apparatus (for example, a display module DM, a window WP, or the like). Differently, the adhesive member AP according to an embodiment having a 180° peel strength of about 200 gf/25 mm or more with respect to a glass substrate under conditions of about 85° C. and about 85% relative humidity exhibits excellent adhesive strength and may stably bond components constituting the electronic apparatus EA (for example, a display module DM, a window WP, or the like). In this specification, the 180° peel strength means that measured by the JIS Z0237 method.

The configuration of the display panel DP illustrated in FIG. 5 or the like is an embodiment and is not limited thereto. For example, the display panel DP may include a liquid crystal display, and in this case, an encapsulation layer TFE may be omitted.

The base substrate BS may provide a base surface on which the circuit layer DP-CL is disposed. The base substrate BS may be a flexible substrate capable of bending, folding, rolling, or the like. The base substrate BS may be a glass substrate, a metal substrate, a polymer substrate, or the like. However, an embodiment of the present disclosure is not limited thereto, and the base substrate BS may include an inorganic layer, an organic layer, or a composite material layer.

The circuit layer DP-CL may include an insulating layer, a semiconductor pattern, a conductive pattern, a signal line, or the like. For example, the circuit layer DP-CL may include a switching transistor and a driving transistor for driving a light emitting element ED (FIG. 6) of a display element layer DP-EL described below.

The display element layer DP-EL may include a light emitting element ED (FIG. 6) that emits light. For example, the light emitting element ED (FIG. 6) may include an organic light emitting material, an inorganic light emitting material, an organic-inorganic light emitting material, a quantum dot, or a quantum rod. For example, the light emitting element ED (FIG. 6) may include a micro LED or a nano LED.

An encapsulation layer TFE may be disposed on the display element layer DP-EL. The encapsulation layer TFE may protect the display element layer DP-EL from foreign substances such as moisture, oxygen, and/or dust particles. The encapsulation layer TFE may include at least one inorganic layer. For example, the encapsulation layer TFE may include an inorganic layer, an organic layer and an inorganic layer, sequentially stacked.

The input sensing part TP may be disposed between the display panel DP and the window WP. The adhesive member AP may be positioned between the input sensing part TP and the window WP. For example, the input detection part TP may be disposed directly on the encapsulation layer TFE of the display panel DP.

In this specification, “one component is directly disposed/provided/formed on another component” means that no third component is disposed/provided/formed between the two components. In other words, “one component is directly disposed/provided/formed” on the other component means that the two components are in “contact.”

The input detection part TP may detect an external input, convert the same into a selected input signal, and provide the input signal to the display panel DP. For example, in the electronic apparatus EA of an embodiment, the input detection part TP may be a touch detection part that detects touch. The input detection part TP may recognize a direct user touch, an indirect user touch, a direct object touch, or an indirect object touch.

The input detection part TP may detect at least one of the location and intensity (pressure) of an externally applied touch. In an embodiment, the input detection part TP may have various structures or be composed of various materials and is not limited to any one embodiment. For example, the input detection part TP may sense an external input using electrostatic capacitance. The display panel DP may receive an input signal from the input detection part TP and generate an image corresponding to the input signal.

The window WP may include a base layer BL and a printed layer BM. Although not illustrated, the window WP may further include at least one functional layer (not illustrated) provided on the base layer BL. For example, the functional layer (not shown) may be a hard coating layer, an anti-fingerprint coating layer, or the like, but an embodiment of the present disclosure is not limited thereto.

The base layer BL may be a glass substrate. Otherwise, the base layer BL may be a plastic substrate. For example, the base layer BL may be formed of polyimide, polyacrylate, polymethylmethacrylate, polycarbonate, polyethylene naphthalate, polyvinylidene chloride, polyvinylidene difluoride, polystyrene, an ethylene-vinyl alcohol copolymer, or a combination thereof.

The printed layer BM may be disposed on one surface of the base layer BL. The printed layer BM may be provided on the lower surface of the base layer BL adjacent to the display module DM. The printed layer BM may be disposed on the edge area of the base layer BL. The printed layer BM may be an ink-printed layer. In addition, the printed layer BM may be a layer formed by including a pigment or dye. In the window WP, the bezel area BZA (FIG. 4) may be a portion where the printed layer BM is provided.

FIG. 6 is a cross-sectional view illustrating a display module DM according to an embodiment. FIG. 6 may be a cross-sectional view illustrating an active area DM-AA of a display module DM. The configuration of the display module DM illustrated in FIG. 6 is an embodiment, and an embodiment of the present disclosure is not limited thereto.

A base substrate BS may include a single layer or multiple layers. For example, the base substrate BS may include a first synthetic resin layer, a single or multilayer inorganic layer, and a second synthetic resin layer disposed on the single or multilayer inorganic layer. Each of the first synthetic resin layer and the second synthetic resin layer may include a polyimide-based resin. In addition, each of the first synthetic resin layer and the second synthetic resin layer may include at least one of an acrylic resin, a methacrylic resin, a polyisoprene-based resin, a vinyl resin, an epoxy-based resin, a urethane-based resin, a cellulose-based resin, a siloxane-based resin, a polyamide-based resin, or a perylene-based resin. In this specification, the “~~-based” resin means one that includes a functional group of “~~.”

A display panel DP may include a transistor TR and a light emitting element ED. The transistor TR and the light emitting element ED may be disposed on the base substrate BS. Although one transistor TR is illustrated in FIG. 6, the display panel DP may substantially include a plurality of transistors and at least one capacitor for driving the light emitting element ED.

A circuit layer DP-CL may be disposed on the base substrate BS. The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the stacked structure of the circuit layer DP-CL illustrated in FIG. 6 is an embodiment, and the stacked structure of the circuit layer DP-CL may vary depending on the configuration of the display panel DP and the process of the circuit layer DP-CL or the like.

The shielding electrode BML may be disposed on the base substrate BS. The shielding electrode BML may overlap the transistor TR. The shielding electrode BML may protect the transistor TR by blocking light incident on the transistor TR from the lower portion of the display panel DP. The shielding electrode BML may include a conductive material. When a voltage is applied to the shielding electrode BML, the threshold voltage of the transistor TR disposed on the shielding electrode BML may be maintained. However, an embodiment of the present disclosure is not limited thereto, and the shielding electrode BML may be a floating electrode. The shielding electrode BML may be omitted.

The buffer layer BFL may be disposed on the base substrate BS to cover the shielding electrode BML. The buffer layer BFL may include an inorganic layer. The buffer layer BFL may improve bonding strength between a semiconductor pattern or a conductive pattern disposed on the buffer layer BFL and the base substrate BS.

The transistor TR may include a source S1, a channel C1, a drain D1 and a gate G1. The source S1, the channel C1 and the drain D1 of the transistor TR may be formed from semiconductor patterns. The semiconductor pattern of the transistor TR may include polysilicon, amorphous silicon, or metal oxide. Any semiconductor material having semiconductor properties may be applied without limitation and is not limited to any one material.

The semiconductor pattern may include multiple regions differentiated by the quantity of conductivity. Regions within the semiconductor pattern doped with dopants or having reduced metal oxides may have high conductivity and may substantially function as the source and drain electrodes of the transistor TR. Regions within the semiconductor pattern with high conductivity may correspond to the source S1 and drain D1 of the transistor TR. Regions within the semiconductor pattern that are undoped or lightly doped, or have non-reduced metal oxides and thus have low conductivity, may correspond to the channel C1 (or active) of the transistor TR.

The first insulating layer INS1 covers the semiconductor pattern of the transistor TR and may be disposed on the buffer layer BFL. The gate G1 of the transistor TR may be disposed on the first insulating layer INS1. On a plane, the gate G1 may overlap the channel C1 of the transistor TR. The gate G1 may function as a mask in a doping process of the semiconductor pattern of the transistor TR.

The second insulating layer INS2 may cover the gate G1 and be disposed on the first insulating layer INS1. The third insulating layer INS3 may be disposed on the second insulating layer INS2.

The connection electrode CNE may include a first connection electrode CNE1 and a second connection electrode CNE2 for electrically connecting the transistor TR and a light emitting element ED. However, the configuration of the connection electrode CNE for electrically connecting the transistor TR and the light emitting element ED is not limited thereto, and one of the first and second connection electrodes CNE1 and CNE2 may be omitted, or an additional connection electrode may be included.

The first connection electrode CNE1 may be disposed on the third insulating layer INS3. The first connection electrode CNE1 may be connected to the drain D1 through a first contact hole CH1 penetrating the first to third insulating layers INS1 to INS3. The fourth insulating layer INS4 may cover the first connection electrode CNE1 and be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 penetrating the fourth and fifth insulating layers INS4 and INS5. The sixth insulating layer INS6 may cover the second connection electrode CNE2 and be disposed on the fifth insulating layer INS5.

Each of the first to sixth insulating layers INS1 to INS6 may include an inorganic layer or an organic layer. For example, the inorganic layer may include at least one of aluminum oxide, titanium oxide, silicon oxide, silicon oxynitride, zirconium oxide or hafnium oxide. The organic layer may include at least one of an acrylic resin, a methacrylic resin, a polyisoprene-based resin, a vinyl resin, an epoxy-based resin, a urethane-based resin, a cellulose-based resin, a siloxane-based resin, a polyamide-based resin or a perylene-based resin.

A display element layer DP-EL may include a pixel definition layer PDL and a light emitting element ED. The light emitting element ED may include a first electrode AE, a hole control layer HCL, a light emitting layer EML, an electron control layer TCL and a second electrode CE. The second electrode CE may be disposed on the first electrode AE. The light emitting layer EML may be disposed between the first electrode AE and the second electrode CE. The hole control layer HCL may be disposed between the first electrode AE and the light emitting layer EML. The electron control layer TCL may be disposed between the light emitting layer EML and the second electrode CE.

The first electrode AE may be disposed on the sixth insulating layer INS6. The first electrode AE may be connected to the second connection electrode CNE2 through a third contact hole CH3 penetrating the sixth insulating layer INS6. The first electrode AE may be electrically connected to the drain D1 of the transistor TR via the first and second connection electrodes CNE1 and CNE2.

The first electrode AE may be formed of a metal material, a metal alloy or a conductive compound. The first electrode AE may be an anode or a cathode. In addition, the first electrode AE may be a pixel electrode. The first electrode AE may be a transmissive electrode, a transflective electrode, or a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn and Zn, a compound of two or more selected therefrom, a mixture of two or more selected therefrom, or an oxide thereof.

When the first electrode AE is a transmissive electrode, the first electrode AE may include a transparent metal oxide, for example, indium tin oxide (ITO), indium zinc oxide (IZO), zinc oxide (ZnO), indium tin zinc oxide (ITZO), or the like. When the first electrode AE is a transflective electrode or a reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (for example, a mixture of Ag and Mg). Alternatively, the first electrode AE may have a multilayer structure including a reflective film or a transflective film formed of the above-described material and a transparent conductive film formed of indium tin oxide (ITO), indium zinc oxide (IZO), zinc oxide (ZnO), indium tin zinc oxide (ITZO), or the like. For example, the first electrode AE may have a three-layer structure of ITO/Ag/ITO, but an embodiment of the present disclosure is not limited thereto. The first electrode AE may include the above-described metal material, a combination of two or more metal materials selected from the above-described metal materials, or an oxide of the above-described metal materials.

The pixel definition layer PDL may be disposed on the sixth insulating layer INS6. A light emitting opening part PX_OP exposing a portion of the first electrode AE may be defined in the pixel definition layer PDL. A portion of the first electrode AE exposed by the light emitting aperture part PX_OP may be defined as a light emitting area LA.

The active area DM-AA of the display module DM may include a light emitting area LA and a light shielding area NLA. The area where the pixel definition layer PDL is disposed may correspond to the light shielding area NLA. The light shielding area NLA may surround the light emitting area LA within the active area DM-AA.

The hole control layer HCL may be disposed on the first electrode AE and the pixel definition layer PDL. The hole control layer HCL may be provided as a common layer overlapping the light emitting area LA and the light shielding area NLA. Unlike the illustration, the hole control layer HCL may also be disposed within the area corresponding to the light emitting aperture part PX_OP. The hole control layer HCL may include at least one of a hole transport layer, a hole injection layer, or an electron blocking layer. The hole control layer HCL may include a known hole injection material and/or a known hole transport material.

The light emitting layer EML may be disposed on the hole control layer HCL. The light emitting layer EML may be disposed in an area corresponding to the light emitting aperture part PX_OP. Differently, the light emitting layer EML may be provided as a common layer. The light emitting layer EML may include an organic light emitting material and/or an inorganic light emitting material. The light emitting layer EML may emit light of any one among red, green and blue colors. For example, the light emitting layer EML may emit blue light.

The electron control layer TCL may be disposed on the light emitting layer EML. The electron control layer TCL may be provided as a common layer overlapping the light emitting area LA and the light shielding area NLA. Unlike the illustration, the electron control layer TCL may also be disposed within the area corresponding to the light emitting aperture part PX_OP. The electron control layer TCL may include at least one of an electron transport layer, an electron injection layer, or a hole blocking layer. The electron control layer TCL may include a known electron injection material and/or a known electron transport material.

The second electrode CE may be disposed on the electron control layer TCL. The second electrode CE may be provided as a common layer overlapping the light emitting area LA and the light shielding area NLA. The second electrode CE may be a common electrode. The second electrode CE may be a cathode or an anode. For example, if the first electrode AE is an anode, the second electrode CE may be a cathode, and if the first electrode AE is a cathode, the second electrode CE may be an anode.

The second electrode CE may be a transmissive electrode, a transflective electrode, or a reflective electrode. When the second electrode CE is a transmissive electrode, the second electrode CE may be formed of a transparent metal oxide, for example, indium tin oxide (ITO), indium zinc oxide (IZO), zinc oxide (ZnO), indium tin zinc oxide (ITZO), or the like.

When the second electrode CE is a transflective electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (for example, AgMg, AgYb, or MgYb). Otherwise, the second electrode CE may have a multilayer structure including a reflective film or a transflective film formed of the above materials and a transparent conductive film formed of indium tin oxide (ITO), indium zinc oxide (IZO), zinc oxide (ZnO), indium tin zinc oxide (ITZO), or the like. For example, the second electrode CE may include the above-described metal material, a combination of two or more metal materials selected from the above-described metal materials, or an oxide of the above-described metal materials.

An encapsulation layer TFE may be disposed on the second electrode CE to cover the light emitting element ED. The encapsulation layer TFE may include a plurality of thin films. For example, the encapsulation layer TFE may include inorganic films disposed on the second electrode CE and an organic film disposed between the inorganic films. The inorganic film may protect the light emitting element ED from moisture/oxygen, and the organic film may protect the light emitting element ED from foreign substances such as dust particles.

An input detection part TP may include a first detection insulating layer IL1, a second detection insulating layer IL2, and a third detection insulating layer IL3. The input detection part TP may include at least one conductive layer disposed on the detection insulating layers. The input detection part TP may include a first conductive layer CDL1 and a second conductive layer CDL2.

The first detection insulating layer IL1 may be disposed on the encapsulation layer TFE. The first detection insulating layer IL1 may include at least one inorganic insulating layer. The first detection insulating layer IL1 may be in contact with the encapsulation layer TFE. Differently, the first detection insulating layer IL1 may be omitted, and in this case, the first conductive layer CDL1 may be in contact with the encapsulation layer TFE.

The first conductive layer CDL1 may be disposed on the first detection insulating layer IL1. The first conductive layer CDL1 may include a plurality of first conductive patterns. The plurality of first conductive patterns may be disposed on the first detection insulating layer IL1. The second detection insulating layer IL2 may be disposed on the first detection insulating layer IL1 to cover at least a portion of the first conductive layer CDL1.

The second conductive layer CDL2 may be disposed on the second detection insulating layer IL2. The second conductive layer CDL2 may include a plurality of second conductive patterns. The plurality of second conductive patterns may be disposed on the second detection insulating layer IL2. Each of the plurality of second conductive patterns may be connected to the plurality of first conductive patterns through a contact hole formed in the second detection insulating layer IL2.

Each of the plurality of first conductive patterns of the first conductive layer CDL1 and the plurality of second conductive patterns of the second conductive layer CDL2 may be disposed corresponding to the light shielding area NLA. Each of the plurality of first conductive patterns of the first conductive layer CDL1 and the plurality of second conductive patterns of the second conductive layer CDL2 may correspond to a mesh pattern.

The third detection insulating layer IL3 may be disposed on the second detection insulating layer IL2 and may cover the second conductive layer CDL2. Each of the second detection insulating layer IL2 and the third detection insulating layer IL3 may include an inorganic insulating layer or an organic insulating layer.

Each of the first conductive layer CDL1 and the second conductive layer CDL2 may have a single layer structure or a multilayer structure stacked along the third direction DR3. The single layer conductive layers CDL1 and CDL2 may include a metal layer or a transparent conductive layer. The metal layer may include molybdenum, silver, titanium, copper, aluminum, or an alloy thereof. The transparent conductive layer may include a transparent conductive oxide, such as indium tin oxide (ITO), indium zinc oxide (IZO), zinc oxide (ZnO), or indium zinc tin oxide (IZTO). In addition, the transparent conductive layer may include a conductive polymer such as PEDOT, metal nanowires and graphene.

The multilayered conductive layers CDL1 and CDL2 may include metal layers. The metal layers may have, for example, a three-layer structure of titanium (Ti)/aluminum (Al)/titanium (Ti). The multilayered conductive layers CDL1 and CDL2 may include at least one metal layer and at least one transparent conductive layer.

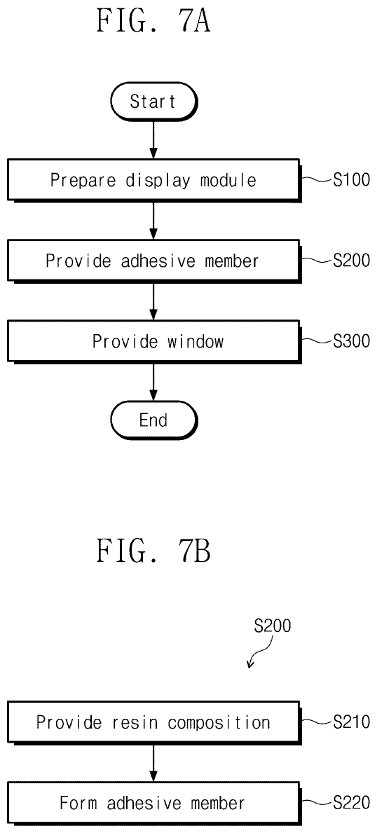

An electronic apparatus according to an embodiment may be manufactured using a method for manufacturing an electronic apparatus according to an embodiment. FIGS. 7A and 7B are flowcharts illustrating a method for manufacturing an electronic apparatus according to an embodiment. FIGS. 8A to 10D are schematic diagrams illustrating manufacturing steps of an electronic apparatus according to an embodiment. In the description of FIGS. 7A to 10D, any overlapping content described with reference to FIGS. 1 to 6 will not be described again, and differences will be mainly described.

Referring to FIG. 7A, a method for manufacturing an electronic apparatus according to an embodiment may include a step of preparing a display module (S100), a step of providing an adhesive member (S200), and a step of providing a window (S300). Prior to the step of providing the window (S300), a step of providing an adhesive member AP (FIG. 5) on the display module DM (FIG. 5) or the window WP (FIG. 5) (S200) may be performed. Referring to FIG. 7B, the step of providing the adhesive member (S200) may include a step of providing a resin composition (S210) and a step of forming an adhesive member (S220).

FIGS. 8A to 8C illustrate a method for manufacturing an electronic apparatus according to an embodiment, including a step of providing a resin composition RC on a display panel DP. Referring to FIG. 8A, the resin composition RC may be provided on the first surface of a display module DM including the display panel DP. The first surface of the display module DM may be the top of the display module DM. The resin composition RC may be provided onto the first surface of the display module DM via a nozzle NZ. While FIG. 8A illustrates the resin composition RC being provided via the nozzle NZ, the device for providing the resin composition RC is not limited thereto.

The resin composition RC of an embodiment may be provided via an inkjet printing method or a dispensing method. The resin composition RC of a liquid phase may be provided in a uniform amount and/or at a uniform rate.

In an embodiment, the resin composition RC may include at least one monofunctional (meth)acrylate compound, at least one photopolymerization initiator, and a dendritic (meth)acrylate copolymer having at least one (meth)acrylate group at at least one terminal. In this specification, a (meth)acryloyl group refers to an acryloyl group or a methacryloyl group, and (meth)acrylate refers to acrylate or methacrylate.

The resin composition RC of an embodiment may include at least one monofunctional (meth)acrylate compound. The monofunctional (meth)acrylate compound may include at least one of an alicyclic (meth)acrylate, a hydroxyl group-containing (meth)acrylate, an alkyl (meth)acrylate, or an aromatic (meth)acrylate. For example, the monofunctional (meth)acrylate compound may include at least one of 4-hydroxybutyl acrylate (4-HBA), isodecyl acrylate (IDAA), tetrahydrofurfuryl acrylate (THF-A), or isobornyl acrylate (IBXA).

The resin composition RC of an embodiment may include at least one photopolymerization initiator. For example, the resin composition RC may include at least one of Omnirad 819 (product of IGM Resins), Esacure One (product of IGM Resins), or Omnirad MBF (product of IGM Resins) as the photopolymerization initiator.

When the resin composition RC includes a plurality of photopolymerization initiators, different photopolymerization initiators may be activated by ultraviolet light of different central wavelengths. For example, the photopolymerization initiators may include at least one of 2,2-dimethoxy-1,2-diphenylethan-1-one, 1-hydroxy cyclohexyl-phenylketone, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

In addition, the photopolymerization initiator may include at least one of 2-methyl-1-[4-(methylthio)phenyl]-2-morpholinopropan-1-one, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenylbis(2,4,6-trimethylbenzoyl)phosphine oxide, [1-(4-phenylsulfanylbenzoyl)heptylideneamino]benzoate, [1-[9-ethyl-6-(2-methylbenzoyl)carbazol-3-yl]ethylideneamino]acetate, or bis(2,4-cyclopentadienyl)bis [2,6-difluoro-3-(1-pyryl)phenyl] titanium(IV).

The resin composition RC of an embodiment may include a dendritic (meth)acrylate copolymer having at least one (meth)acrylate group at at least one terminal. The dendritic (meth)acrylate copolymer refers to a copolymer having a “resin phase structure,” and the “resin phase structure” refers to a structure including a core part and an arm part directly or indirectly bonded to the core part. The core part may be composed of a single element or multiple elements. The arm part may be composed of multiple elements.

The dendritic (meth)acrylate copolymer may include at least one (meth)acrylate group at at least one terminal. A resin composition including the dendritic (meth)acrylate copolymer having at least one (meth)acrylate group at at least one terminal may selectively segregate at the interface with the air during curing of the resin composition, thereby enhancing cohesion at the interface. The resin composition RC of an embodiment may efficiently segregate at the interface by including the dendritic (meth)acrylate copolymer according to an embodiment, thereby reducing entanglement between polymer chains or between a polymer and a matrix monomer, and may selectively enhance adhesion at the interface. Therefore, an adhesive member AP formed from the resin composition RC of an embodiment including the dendritic (meth)acrylate copolymer according to an embodiment may exhibit reduced stiffness. In addition, the adhesive member AP (FIG. 4) formed from the resin composition RC including the dendritic (meth)acrylate copolymer according to an embodiment may satisfy the aforementioned 180° peel strength.

In an embodiment, the dendritic (meth)acrylate copolymer may be synthesized using a (meth)acrylate monomer and a radical polymerization initiator. The (meth)acrylate monomer may include at least one of methyl methacrylate (MMA) or isobornyl methacrylate (IBXMA).

The dendritic (meth)acrylate copolymer, which includes at least one (meth)acrylate group at at least one terminal, may include a (meth)acrylate at a structural terminal. The (meth)acrylate at the structural terminal has high reactivity and may block reaction with oxygen. The (meth)acrylate at the structural terminal of the dendritic (meth)acrylate copolymer may trap oxygen radicals that cause curing inhibition at the outermost surface.

The dendritic (meth)acrylate copolymer according to an embodiment may segregate on the outermost surface during photocuring the resin composition RC, thereby securing adhesiveness through a certain cohesive force, while suppressing (or preventing) environmental degradation due to heat/light at the interface with the air. The outermost surface refers to the outermost surface of the resin composition applied for photocuring and may be the surface closest to the atmosphere. Accordingly, the resin composition RC according to an embodiment may exhibit a 180° peel strength of about 1500 gf/25 mm or more against a glass substrate at about 25° C. after photocuring in the atmosphere. In addition, the resin composition RC according to an embodiment may exhibit a 180° peel strength of about 200 gf/25 mm or more against a glass substrate at about 85° C. and about 85% relative humidity after photocuring in the atmosphere.

When forming an adhesive member by irradiating a resin composition with light in the atmosphere, oxygen in the atmosphere inhibits the curing of the surface. The radicals produced by the cleavage of the photopolymerization initiator by light and the terminal radicals of (meth)acrylate groups that grow through polymerization are consumed by oxygen in the atmosphere at the interface between the atmosphere and the surface (that is, the surface of the applied resin composition) to form peroxide radicals, thereby inhibiting polymerization by a polymerization reaction. The polymerization of the reactants provided during the polymerization reaction forms an adhesive member, which is a cured product of the resin composition. In contrast, the resin composition RC of an embodiment includes the dendritic (meth)acrylate copolymer having at least one (meth)acrylate group at at least one terminal, thereby exhibiting excellent processability during photocuring in the atmosphere.

The resin composition RC including the dendritic (meth)acrylate copolymer according to an embodiment may be cured in the atmosphere in a short time. The terminal (meth)acrylate group included in the dendritic (meth)acrylate copolymer has high reactivity and contributes to a high crosslinking density. Accordingly, the resin composition RC of an embodiment may be cured in a short time.

In an embodiment, the weight average molecular weight of the dendritic (meth)acrylate copolymer may be about 3,000 or more and about 30,000 or less. For example, the weight average molecular weight of the dendritic (meth)acrylate copolymer may be about 8,000 or more. An adhesive member AP (FIG. 4) formed from the resin composition RC including the dendritic (meth)acrylate copolymer having a weight average molecular weight of about 3,000 or more may satisfy the 180° peel strength described above.

The resin composition RC of an embodiment may further include at least one urethane (meth)acrylate having a weight average molecular weight of about 4,000 or more and about 50,000 or less. The urethane (meth)acrylate having a weight average molecular weight of about 4,000 or more and about 50,000 or less is incorporated into the resin composition RC as an oligomer with a relatively high polymerization degree, and the polymerization degree is maintained even after photocuring, thereby forming an adhesive member AP (FIG. 4) with excellent adhesion reliability that satisfies the aforementioned 180° peel strength.

Also, in an embodiment, the weight of the urethane (meth)acrylate may be about 1 wt % or more and about 20 wt % or less based on 100 wt % of the total weight of the resin composition RC. For example, the weight of the urethane (meth)acrylate may be about 1.5 wt % or more and about 10 wt % or less based on 100 wt % of the total weight of the resin composition RC. However, this is an embodiment, and the weight of the urethane (meth)acrylate is not limited thereto.

The urethane (meth)acrylate may include UV-3300B (urethane acrylate oligomer, product of Mitsubishi Chemical). However, this is an embodiment, and the urethane (meth)acrylate contained in the resin composition RC is not limited thereto.

The resin composition RC of an embodiment may have a shear viscosity of about 10 mPa·s or more and about 50 mPa·s or less, as measured at about 30° C. according to the JISZ8803 method. The resin composition RC having a shear viscosity of about 50 mPa·s or less, as measured at about 30° C., may be easily discharged from a device such as a nozzle (NZ), and a uniform discharge speed and amount may be maintained. Accordingly, the resin composition RC of an embodiment may be easily provided by controlling the desired discharge amount through an inkjet printing method or a dispensing method. A resin composition having a shear viscosity exceeding about 50 mPa·s measured at 30° C. is not easily discharged from a device such as a nozzle NZ, and may not be applied in a uniform amount and/or thickness.

The resin composition RC of an embodiment may have a 180° peel strength of about 1500 gf/25 mm or more against a glass substrate at about 25° C. after being photocured in the air. In addition, the resin composition RC of an embodiment may have a 180° peel strength of about 200 gf/25 mm or more against a glass substrate under conditions of about 85° C. and about 85% relative humidity after being photocured in the air.

Referring to FIGS. 8A and 8B, a resin composition RC may be directly applied onto the first surface of a display module DM, and light LT may be irradiated onto the resin composition RC applied to a predetermined thickness. For example, the light LT may be ultraviolet light. After the light LT is irradiated, the resin composition RC may be cured to form an adhesive member AP as illustrated in FIG. 8C. After the adhesive member AP is formed, a window WP may be attached to one surface of the adhesive member AP.

In an embodiment, the light LT may include UVA and UVV and have an accumulated illuminance of about 900 mW and an accumulated light quantity of about 1800 mJ/cm². The light LT may be irradiated onto the resin composition RC in the air. The resin composition RC of an embodiment may prevent (or minimize) inhibition due to oxygen in the atmosphere and exhibit excellent processability by including the dendritic (meth)acrylate copolymer according to an embodiment.

In FIG. 8B, the light LT is illustrated as being directly irradiated onto the resin composition RC. However, unlike the illustration, a carrier film (not shown) may be disposed on the resin composition RC. The carrier film may be transparent to ultraviolet light.

In FIGS. 8A to 8C, the resin composition RC is illustrated as being cured once (that is, cured by providing light once) to form the adhesive member AP. However, an embodiment of the present disclosure is not limited thereto. For example, the resin composition RC may be cured twice or more to form the adhesive member AP.

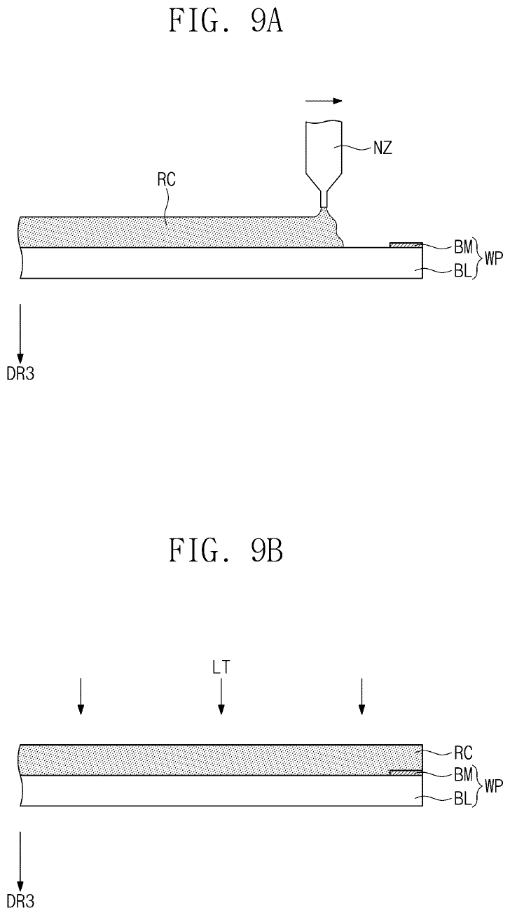

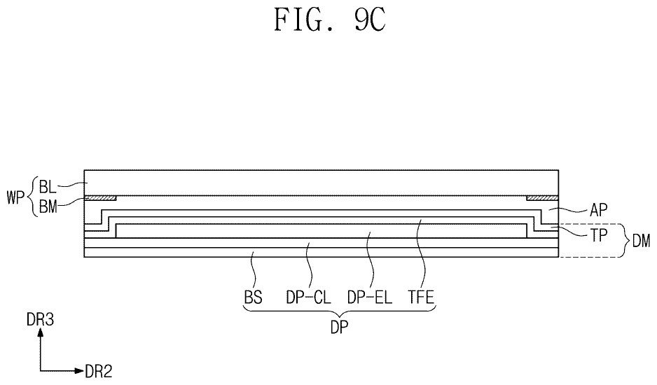

FIGS. 9A to 9C are diagrams illustrating a step of providing an adhesive member according to another embodiment of the present disclosure. Hereinafter, in the description of FIGS. 9A to 9C, any overlapping content with that described with reference to FIGS. 1 to 8C will not be described again, and differences will be mainly described.

The manufacturing method illustrated in FIGS. 9A to 9C may illustrate a method for manufacturing an electronic apparatus of an embodiment, including a step of providing a resin composition RC on a window WP. Referring to FIG. 9A, the resin composition RC may be provided on the second surface of the window WP through a nozzle NZ. The resin composition RC may be directly provided on the second surface of the window WP. The second surface of the window WP may be the bottom of the window WP.

Referring to FIGS. 9B and 9C, light LT may be provided to the resin composition RC applied to a certain thickness, and the resin composition RC may be cured by the light LT to form an adhesive member AP. Subsequently, a display module DM may be attached to one surface of the adhesive member AP.

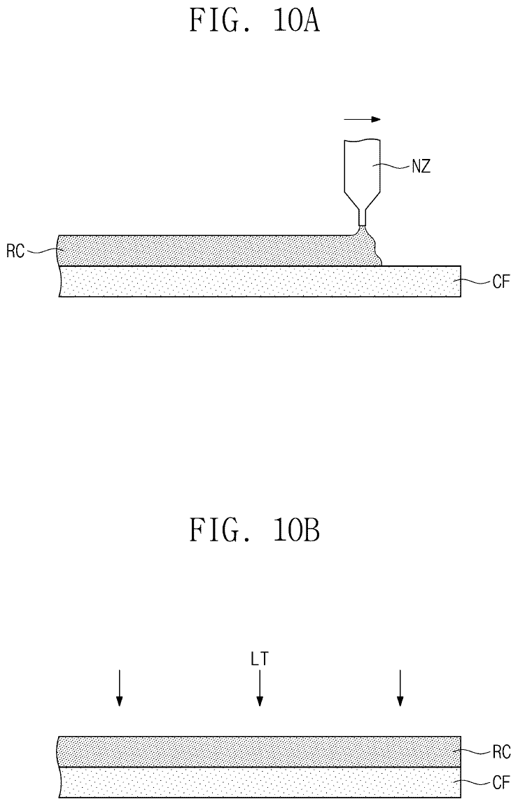

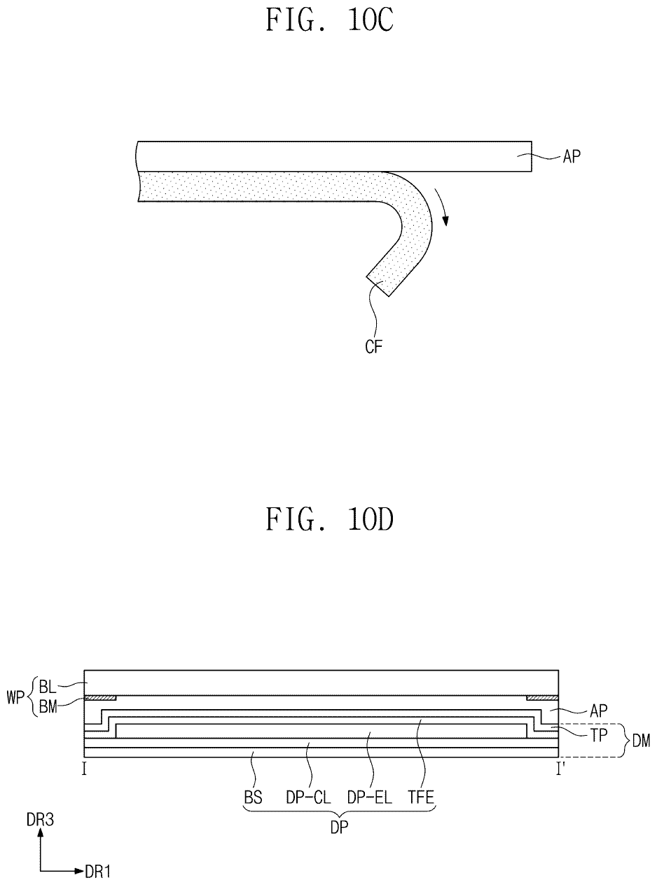

FIGS. 10A to 10D are diagrams illustrating a step for providing an adhesive member according to another embodiment of the present disclosure. In the description of FIGS. 10A to 10D, any overlapping content with that described with reference to FIGS. 1 to 9C will not be described again, and differences will be mainly described.

Referring to FIG. 10A, a resin composition RC may be provided onto a substrate CF via a nozzle NZ. For example, the substrate CF on which the resin composition RC is provided may include polyethylene terephthalate (PET). The substrate CF is a temporary substrate used to form an adhesive member AP (FIG. 10D) from the resin composition RC, and any substrate that may be easily detached after the resin composition RC is cured may be used without limitation. One surface of the substrate CF on which the resin composition RC is provided may be subjected to a release treatment.

Referring to FIGS. 10B and 10C, the resin composition RC applied to a certain thickness on the substrate CF may be irradiated with light LT to form an adhesive member AP. The resin composition RC may be cured by the light LT to form the adhesive member AP. Referring to FIGS. 10C and 10D, the adhesive member AP thus formed may be detached from the substrate CF and provided on the first side of a display module DM or the second side of a window WP. The one side of the adhesive member AP may be laminated on the first side of the display module DM or the second side of the window WP, and the third side of the window WP or the fourth side of the display module DM, which is not attached to the remaining side of the adhesive member AP, may be attached. In the display module DM, the first side and the fourth side may be spaced apart from each other in the thickness direction DR3. In the window WP, the second and third sides may be spaced apart in the thickness direction DR3.

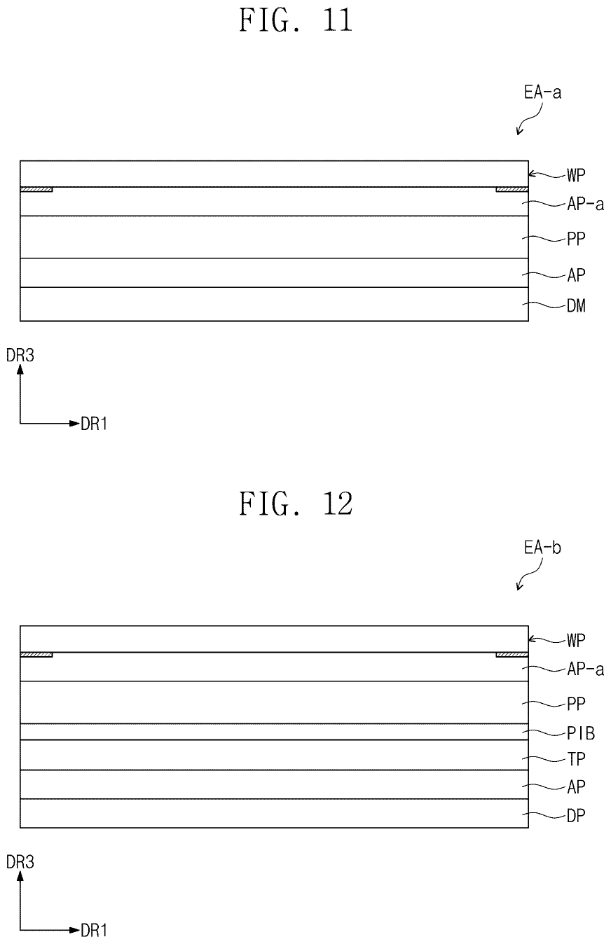

FIGS. 11 and 12 are cross-sectional views illustrating electronic apparatuses according to other embodiments of the present disclosure. In the description of FIGS. 11 and 12, any overlap with the descriptions with reference to FIGS. 1 to 10D will not be explained again, and differences will be mainly described.

Compared to the electronic apparatus EA illustrated in FIGS. 4 and 5, the electronic apparatus EA-a illustrated in FIG. 11 may further include a light control layer PP and an optical adhesive layer AP-a. The electronic apparatus EA-a of an embodiment may further include a light control layer PP disposed between an adhesive member AP and a window WP, and an optical adhesive layer AP-a disposed between the light control layer PP and the window WP. For example, the light control layer PP may include a color filter layer or a polarizing plate.

The optical adhesive layer AP-a may include a polymer obtained from the resin composition RC (FIGS. 8A, 9A and 10A) according to an embodiment. The optical adhesive layer AP-a including the polymer obtained from the resin composition RC (FIGS. 8A, 9A and 10A) may have a 180° peel strength of about 1500 gf/25 mm or more against a glass substrate at about 25° C. The optical adhesive layer AP-a including the polymer obtained from the resin composition RC (FIGS. 8A, 9A and 10A) may have a 180° peel strength of about 200 gf/25 mm or more against a glass substrate under conditions of about 85° C. and about 85% relative humidity. Accordingly, an electronic apparatus EA-a including the optical adhesive layer AP-a may exhibit excellent reliability.

Compared to the electronic apparatus EA illustrated in FIGS. 4 and 5, the electronic apparatus EA-b of an embodiment illustrated in FIG. 12 may further include a light control layer PP, an optical adhesive layer AP-a, and an interlayer adhesive layer PIB. The electronic apparatus EA-b of an embodiment illustrated in FIG. 12 may further include, like the electronic apparatus EA-a of an embodiment illustrated in FIG. 11, a light control layer PP disposed between an adhesive member AP and a window WP, and an optical adhesive layer AP-a disposed between the light control layer PP and the window WP.

In the electronic apparatus EA-b of an embodiment, the adhesive member AP may be provided between a display panel DP and an input detection part TP. That is, the input detection part TP may not be directly disposed on the display panel DP, but rather, the display panel DP and the input detection part TP may be coupled to each other by the adhesive member AP. For example, the adhesive member AP may be disposed between the encapsulation layer TFE (FIG. 5) of the display panel DP and the input detection part TP.

The interlayer adhesive layer PIB may be provided on the lower side of the light control layer PP. The interlayer adhesive layer PIB may be disposed between the input detection part TP and the light control layer PP and may be formed of an adhesive material having excellent moisture permeability. For example, the interlayer adhesive layer PIB may be formed by including polyisobutylene. The interlayer adhesive layer PIB may be disposed on the input detection part TP to prevent corrosion of detection electrodes of the input detection part TP. The electronic apparatus EA-b of an embodiment may exhibit excellent reliability by including the optical adhesive layer AP-a and the adhesive member AP formed from the resin composition RC (FIGS. 8A, 9A and 10A) according to an embodiment.

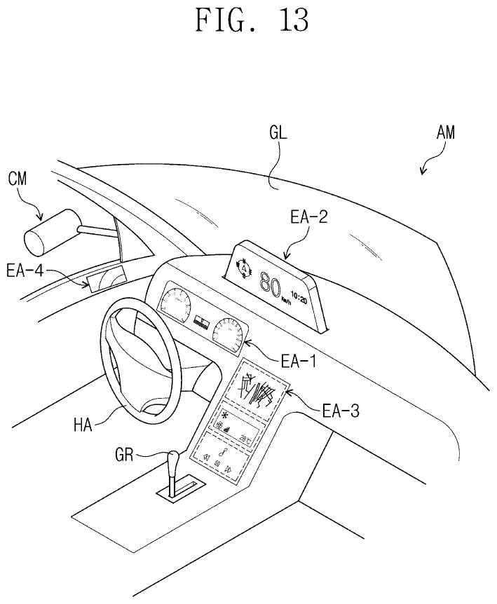

FIG. 13 is a diagram showing a vehicle AM in which first to fourth electronic apparatuses EA-1, EA-2, EA-3 and EA-4 are disposed. At least one of the first to fourth electronic apparatuses EA-1, EA-2, EA-3 and EA-4 may include the same configuration as any one of the electronic apparatuses EA, EA-a and EA-b of embodiments described with reference to FIGS. 1 to 5, 11 and 12. At least one of the first to fourth electronic apparatuses EA-1, EA-2, EA-3 and EA-4 may include the adhesive member AP of an embodiment described with reference to FIGS. 1 to 5, 11 and 12.

Although the vehicle AM in FIG. 13 is shown as an automobile, this is an embodiment, and the first to fourth electronic apparatuses EA-1, EA-2, EA-3 and EA-4 may also be disposed on other transportation means such as bicycles, motorcycles, trains, ships and airplanes. In addition, at least one of the first to fourth electronic apparatuses EA-1, EA-2, EA-3 and EA-4 that includes the same configuration as any of the electronic apparatuses EA, EA-a and EA-b (FIGS. 5, 11 and 12) of embodiments may be employed in other electronic apparatuses without departing from the spirit of the present disclosure.

At least one of the first to fourth electronic apparatuses EA-1, EA-2, EA-3 and EA-4 may include the adhesive member AP (FIG. 5) of an embodiment. The adhesive member AP (FIG. 5) of an embodiment may be formed from the resin composition RC (FIGS. 8A, 9A and 10A) of an embodiment and may exhibit excellent adhesive strength.

Referring to FIG. 13, a vehicle AM may include a steering wheel HA and a gear shifter GR for operating the vehicle AM, and a front window GL may be disposed to face the driver.

The first electronic apparatus EA-1 may be disposed in a first area overlapping the steering wheel HA. For example, the first electronic apparatus EA-1 may be a digital cluster displaying first information of the vehicle AM. The first information may include a first scale indicating the driving speed of the vehicle AM, a second scale indicating the engine rotational speed (that is, revolutions per minute (RPM)), and an image indicating the fuel condition. The first scale and the second scale may be displayed as digital images.

The second electronic apparatus EA-2 may be disposed in a second area facing the driver's seat and overlapping the front window GL. The driver's seat may be a seat where the steering wheel HA is positioned. For example, the second electronic apparatus EA-2 may be a head-up display (HUD) that displays second information about the vehicle AM. The second electronic apparatus EA-2 may be optically transparent. The second information includes a digital number indicating the driving speed of the vehicle AM and may further include information such as the current time. Unlike the illustration, the second information of the second electronic apparatus EA-2 may be projected and displayed on the front window GL.

The third electronic apparatus EA-3 may be disposed in a third area adjacent to the gear shifter GR. For example, the third electronic apparatus EA-3 may be a center information display (CID) that is disposed between the driver's seat and the passenger seat and displays the third information. The passenger seat may be separated from the driver's seat with the gear shifter GR therebetween. The third information may include information regarding road conditions (for example, navigation information), music or radio playback, dynamic video (or image) playback, and the temperature inside the vehicle AM.

The fourth electronic apparatus EA-4 may be disposed in a fourth area adjacent to the side of the vehicle AM and separated from the steering wheel HA and the gear shifter GR. For example, the fourth electronic apparatus EA-4 may be a digital side mirror that displays the fourth information. The fourth electronic apparatus EA-4 may display an image of the exterior of the vehicle AM captured by a camera module CM disposed outside the vehicle AM. The fourth information may include an image of the exterior of the vehicle AM.

The first to fourth information described above are illustrations, and the first to fourth electronic apparatuses EA-1, EA-2, EA-3 and EA-4 may further display information regarding the interior and exterior of the vehicle. The first to fourth pieces of information may include different information. However, an embodiment of the present disclosure is not limited thereto, and some of the first to fourth pieces of information may include the same information.

Hereinafter, a resin composition according to an embodiment of the present disclosure and an adhesive member formed from the resin composition will be described in detail with reference to examples and comparative examples. In addition, the examples shown below are examples to aid understanding of the present disclosure, and the scope of the present disclosure is not limited thereto.

### EXAMPLE

### 1. Synthesis of (Meth)acrylate Copolymers

(Meth)acrylate copolymers D-1 to D-5 and L-1 provided in the resin compositions of the Examples and Comparative Examples were synthesized by the methods described below. The (meth)acrylate copolymers D-1 to D-3 are dendritic (meth)acrylate copolymers of the Examples having a (meth)acrylate group at the terminal, the (meth)acrylate copolymers D-4 and D-5 are dendritic (meth)acrylate copolymers of the Comparative Examples not having a (meth)acrylate group at the terminal, and the (meth)acrylate copolymer L-1 is a linear (meth)acrylate copolymer of the Comparative Examples having a (meth)acrylate group at the terminal.

### <Synthesis of (Meth)acrylate Copolymer D-1>

To a round-bottom flask equipped with a condenser, a dropping funnel, a nitrogen inlet tube, and a magnetic stirrer, 60 g of propylene glycol 1-monomethyl ether (product of Tokyo Kasei Kogyo), 25.0 g of methyl methacrylate (MMA, product of Tokyo Kasei Kogyo), 13.8 g of isobornyl methacrylate (IBXMA, product of Tokyo Kasei Kogyo), 0.32 g of V-501 (4,4′-azobis(4-cyanovaleric acid), product of Fujifilm Wako Pure Chemical Industries, Ltd.), and 2.6 g of KarenzMT TPMB (trimethylol propane tris(3-mercaptopropionate), product of Resonac) were added and reacted for about 4 hours at about 80° C. under a nitrogen atmosphere to obtain a sample. After cooling, the sample was added to methanol, and the precipitated solid was vacuum-dried to obtain the precursor of D-1.

To a round-bottom flask equipped with a condenser and a magnetic stirrer, 30 g of the precursor of D-1, 75 mL of propylene glycol 1-monomethyl ether, 0.30 g of triphenyl phosphine (TPP, product of Fujifilm Wako Pure Chemical Industries, Ltd.), and 60 mg of 4-methoxyphenol (MEHQ, product of Tokyo Kasei Kogyo) were added and heated in an oil bath to about 120° C. Then, 4.7 g of glycidyl methacrylate (GMA, product of Tokyo Kasei Kogyo) was added thereto and reacted for about 4 hours to obtain a sample. After cooling, the sample was added to a large volume of ethanol, reprecipitated, purified, and vacuum-dried to obtain (meth)acrylate copolymer D-1.

### <Synthesis of (Meth)acrylate Copolymer D-2>

To a round-bottom flask equipped with a condenser, a dropping funnel, a nitrogen inlet tube, and a magnetic stirrer, 60 g of propylene glycol 1-monomethyl ether (product of Tokyo Kasei Kogyo), 25.0 g of methyl methacrylate (MMA, product of Tokyo Kasei Kogyo), 13.8 g of isobornyl methacrylate (IBXMA, product of Tokyo Kasei Kogyo), 0.30 g of V-501 (4,4′-azobis(4-cyanovaleric acid), product of Fujifilm Wako Pure Chemical Industries, Ltd.), and 1.0 g of KarenzMT TPMB (trimethylol propane tris(3-mercaptopropionate, product of Resonac) were added and reacted for about 4 hours at about 80° C. under a nitrogen stream to obtain a sample. After cooling, the sample was added to methanol, and the precipitated solid was vacuum-dried to obtain the precursor of D-2.

To a round-bottom flask equipped with a condenser and a magnetic stirrer, 30 g of the precursor of D-2, 75 mL of propylene glycol 1-monomethyl ether, 0.30 g of triphenyl phosphine (TPP, product of Fujifilm Wako Pure Chemical Industries, Ltd.), and 60 mg of 4-methoxyphenol (MEHQ, product of Tokyo Kasei Kogyo) were added and heated in an oil bath to about 120° C. Then, 6.8 g of glycidyl methacrylate (GMA, product of Tokyo Kasei Kogyo) was added thereto and reacted for about 4 hours to obtain a sample. After cooling, the sample was added to a large volume of ethanol, reprecipitated, purified, and vacuum-dried to obtain (meth)acrylate copolymer D-2.

### <Synthesis of (Meth)acrylate Copolymer D-3>

To a round-bottom flask equipped with a condenser, dropping funnel, nitrogen inlet tube, and a magnetic stirrer, 60 g of propylene glycol 1-monomethyl ether (product of Tokyo Kasei Kogyo), 20.0 g of methyl methacrylate (MMA, product of Tokyo Kasei Kogyo), 11.1 g of isobornyl methacrylate (IBXMA, product of Tokyo Kasei Kogyo), 0.25 g of V-501 (4,4′-azobis(4-cyanovaleric acid), product of Fujifilm Wako Pure Chemical Industries, Ltd.), and 0.63 g of KarenzMT PE1 (pentaerythritol tetrakis(3-mercaptopropionate), product of Resonac) were added and reacted for about 4 hours at about 80° C. under a nitrogen stream to obtain a sample. After cooling, the sample was added to methanol, and the precipitated solid was vacuum-dried to obtain the precursor of D-3.

To a round-bottom flask equipped with a condenser and a magnetic stirrer, 4.0 g of the precursor of D-3, 10 mL of propylene glycol 1-monomethyl ether, 40 mg of triphenyl phosphine (TPP, product of Fujifilm Wako Pure Chemical Industries, Ltd.), and 8.0 mg of 4-methoxyphenol (MEHQ, product of Tokyo Kasei Kogyo) were added and heated in an oil bath to about 120° C. Then, 0.57 g of glycidyl methacrylate (GMA, product of Tokyo Kasei Kogyo) was added thereto, and the reaction was carried out for about 4 hours to obtain a sample. After cooling, the sample was added to a large amount of ethanol, reprecipitated, purified, and vacuum-dried to obtain (meth)acrylate copolymer D-3.

### <Synthesis of (Meth)acrylate Copolymer D-4>

To a round-bottom flask equipped with a condenser, a dropping funnel, a nitrogen inlet tube, and a magnetic stirrer, 60 g of propylene glycol 1-monomethyl ether (product of Tokyo Kasei Kogyo), 25.0 g of methyl methacrylate (MMA, product of Tokyo Kasei Kogyo), 13.8 g of isobornyl methacrylate (IBXMA, product of Tokyo Kasei Kogyo), 0.30 g of V-501 (4,4′-azobis(4-cyanovaleric acid), product of FUJIFILM Wako Pure Chemical Industries, Ltd.), and 2.6 g of KarenzMT TPMB (trimethylol propane tris(3-mercaptopropionate), product of Resonac) were added and reacted at about 80° C. for about 4 hours under a nitrogen atmosphere to obtain a sample. After cooling, the sample was added to methanol, and a solid precipitate obtained was reprecipitated, purified and vacuum-dried to obtain (meth)acrylate copolymer D-4.

### <Synthesis of (Meth)acrylate Copolymer D-5>

To a round-bottom flask equipped with a condenser, a dropping funnel, a nitrogen inlet tube, and a magnetic stirrer, 60 g of propylene glycol 1-monomethyl ether (product of Tokyo Kasei Kogyo), 26.0 g of methyl methacrylate (MMA, product of Tokyo Kasei Kogyo), 15.0 g of isobornyl methacrylate (IBXMA, product of Tokyo Kasei Kogyo), 0.30 g of V-601 (dimethyl 2,2′-azobis(2-methylpropionate), product of Fujifilm Wako Pure Chemical Industries, Ltd.), and 0.57 g of KarenzMT PE1 (pentaerythritol tetrakis(3-mercaptopropionate), product of Resonac) were added and reacted at about 80° C. for about 4 hours under a nitrogen atmosphere to obtain a sample. After cooling, the sample was added to methanol. The precipitated solid obtained was reprecipitated, purified and vacuum-dried to obtain (meth)acrylate copolymer D-5.

### <Synthesis of (Meth)acrylate Copolymer L-1>

To a round-bottom flask equipped with a condenser, a dropping funnel, a nitrogen inlet tube, and a magnetic stirrer, 60 g of propylene glycol 1-monomethyl ether (product of Tokyo Kasei Kogyo) was added, bubbled with nitrogen for about 30 minutes and heated at about 80° C. Separately, 15 g of 1,3-dimethyl-2-imidazolidinone (product of Fujifilm Wako Pure Chemical Industries, Ltd.), 24.0 g of methyl methacrylate (MMA, product of Tokyo Kasei Kogyo), 13.3 g of isobornyl methacrylate (IBXMA, product of Tokyo Kasei Kogyo), and 2.5 g of V-501 (4,4′-azobis(4-cyanovaleric acid), product of Fujifilm Wako Pure Chemical Industries, Ltd.) were added and stirred to prepare an initiator and monomer solution. After confirming homogeneity, the initiator and monomer solution was added dropwise to the propylene glycol 1-monomethyl ether. After the dropwise addition, the reaction was carried out at about 80° C. for about 4 hours to obtain a sample. After cooling, the sample was added to a large amount of ethanol and vacuum-dried to obtain the precursor of L-1.

To a round-bottom flask equipped with a condenser and a magnetic stirrer, 5.0 g of the precursor of L-1, 20 mL of dimethylformamide (DMF), 50 mg of triphenylphosphine (TPP, product of Fujifilm Wako Pure Chemical Industries, Ltd.), and 5.0 mg of 4-methoxyphenol (MEHQ, product of Tokyo Kasei Kogyo) were added and heated in an oil bath to about 120° C. Then, 1.0 g of glycidyl methacrylate (GMA, product of Tokyo Kasei Kogyo) was added thereto and reacted for about 6 hours to obtain a sample. After cooling, the sample was added to a large volume of ethanol, reprecipitated, purified, and vacuum-dried to obtain (meth)acrylate copolymer L-1.

Table 1 below lists the materials used in the synthesis of the synthesized (meth)acrylate copolymers D-1 to D-5 and L-1 and physical properties. The properties were measured using the methods described below.

### <Molecular Weight Measurement of (Meth)acrylate Copolymers>

The molecular weight was measured using a gel permeation chromatography (GPC) analyzer, HLC-8420GPC, manufactured by TOSOH Corporation. TSKgel SUPER HZM-N was used as a measurement column, tetrahydrofuran (THF) was used as a measurement solvent, and the weight average molecular weight value was applied by conversion to standard polystyrene (PS) from the Size Exclusion Chromatography (SEC) curve detected by a refractive index (RI) detector.

### <Glass Transition Temperature Measurement>

The glass transition temperature was measured using a Photo-DSC 204 Phoenix differential scanning calorimeter (DSC), product of NETZSCH, at a heating rate of about 10 K/min. The results of the second scan are included in the material data in Table 1.

TABLE 1

| | (Meth)acrylate copolymer | | | | | |
|---|---|---|---|---|---|---|
| | D-1 | D-2 | D-3 | D-4 | D-5 | L-1 |
| First monomer | MMA | MMA | MMA | MMA | MMA | MMA |
| Second monomer | IBXMA | IBXMA | IBXMA | IBXMA | IBXMA | IBXMA |
| Third monomer | — | — | — | — | — | LMA |
| Chain transfer agent | KarenzMT | KarenzMT | KarenzMT | KarenzMT | KarenzMT | — |
| | TPMB | TPMB | PE1 | TPMB | PE1 | |
| Initiator | V-501 | V-501 | V-501 | V-501 | V-601 | V-501 |
| Presence or absence of | ∘ | ∘ | ∘ | x | x | ∘ |
| (meth)acrylate group at | | | | | | |
| the terminal | | | | | | |
| Structure | Dendritic | Dendritic | Dendritic | Dendritic | Dendritic | Linear |
| Valence | 3 | 3 | 4 | 3 | 4 | 0 (linear) |
| Weight average | 8,800 | 17,000 | 22,000 | 8,800 | 23,000 | 10,000 |
| molecular weight | | | | | | |

### <Material Data in Table 1>

MMA: Methyl methacrylate (product of Tokyo Kasei Kogyo, homopolymer glass transition temperature: 105° C.)
IBXMA: Isobornyl methacrylate (product of Tokyo Kasei Kogyo, homopolymer glass transition temperature: 180° C.)
LMA: Lauryl methacrylate (product of Tokyo Kasei Kogyo, homopolymer glass transition temperature: −65° C.)
KarenzMT TPMB: Trimethylol propane tris(3-mercaptopropionate), (product of Resonac)
KarenzMT PE1: Pentaerythritol tetrakis(3-mercaptopropionate), (product of Resonac)
V-501:4,4′-Azobis(4-cyanovaleric acid) (product of Fujifilm Wako Junyaku)
V-601: Dimethyl 2,2′-azobis(2-methylpropionate) (product of Fujifilm Wako Junyaku)

Referring to Table 1, (meth)acrylate copolymers D-1 to D-3 have a dendritic structure including a (meth)acrylate group at the terminal. (Meth)acrylate copolymers D-4 and D-5 have a dendritic structure without a (meth)acrylate group at the terminal. (Meth)acrylate copolymer L-1 has a linear structure with a (meth)acrylate group at the terminal.

Referring to Table 1, (meth)acrylate copolymers D-1 to D-5 have a valence of 3 or 4 and correspond to a dendritic (meth)acrylate copolymer having a resin phase structure with three or four monomer groups branched from a core. (Meth)acrylate copolymer L-1 has a valence of 0 and corresponds to a linear (meth)acrylate copolymer having a linear structure.

(Meth)acrylate copolymers D-1 to D-3 are synthesized using a (meth)acrylate monomer and a radical polymerization initiator. The (meth)acrylate monomer includes at least one among methyl methacrylate (MMA) and isobornyl methacrylate (IBXMA). (Meth)acrylate copolymers D-1 to D-3 have a weight average molecular weight of about 3,000 or more and satisfy the weight average molecular weight of the dendritic (meth)acrylate copolymer according to an embodiment.

### 2. Preparation and Evaluation of Resin Compositions

The resin compositions of the Examples and Comparative Examples were prepared according to the mixing ratios (unit: parts by weight) shown in Tables 2 to 4. The materials disclosed in Tables 2 to 4 were provided in light-shielding glass vials at respective weight ratios. The materials were stirred by a roll mill at room temperature for about 12 hours to prepare the resin compositions of the Examples and Comparative Examples.

### <Measurement of Shear Viscosity of Resin Compositions>

The shear viscosity of the resin compositions in Tables 2 to 4 were measured at about 30° C. using a TVE-25L viscometer (product of Toki Sangyo) according to the JIS Z8803 method, and are recorded in Tables 2 to 4.

### 3. Preparation and Evaluation of Adhesive Members

The 180° peel strength of the adhesive members formed from the resin compositions of the Examples and Comparative Examples was evaluated and recorded in Tables 2 to 4. The adhesive members of the Examples were formed from the resin compositions of Examples 1 to 4. Furthermore, the adhesive members of the Comparative Examples were formed from the resin compositions of Comparative Examples 5 to 16.

### <Measurement of 180° Peeling Strength of Adhesive Members>

Each of the resin compositions of the Examples and Comparative Examples was applied to a thickness of about 100 μm on a soda-lime glass (product of Central Glass Co., Ltd.) with a size of about 26 mm×76 mm, by using an inkjet printer (product of MICROJET). The soda-lime glass onto which each resin composition was applied was irradiated with light using an LED lamp such that the total accumulated light quantity was about 1,800 mJ/cm². A PET film (A4360 50 μm, product of Toyobo Co., Ltd.) with a size of about 20 mm×150 mm was provided onto the irradiated resin composition and bonded at a bonding pressure of about 0.15 MPa to obtain a sample.

The peel strength of the sample obtained was measured at about 25° C. in accordance with the JIS Z0237 method. In addition, the peel strength of the sample obtained was measured under conditions of about 85° C. and about 85% relative humidity (RH) in accordance with the JIS Z0237 method. The average value for about 50 mm of peeling was obtained, the obtained value was multiplied by 1.25, and the peel strength for a width of about 25 mm was recorded in Tables 2 to 4. In Table 4, the peel strength of the resin composition of Comparative Example 16 was not measured, because inkjet discharge was impossible.

### <Material Data in Tables 2 to 4>

4-HBA: 4-Hydroxybutyl acrylate (product of Osaka Organic Chemical Industry Co., Ltd.)
IDAA: Isodecyl acrylate (product of Osaka Organic Chemical Industry Co., Ltd.)
THF-A: Tetrahydrofurfuryl acrylate (product of Kyoeisha Chemical Co., Ltd.)
IBXA: Isobornyl acrylate (product of Osaka Organic Chemical Industry Co., Ltd.)
Omnirad 819: Phenylbis(2,4,6-trimethylbenzoyl)phosphine oxide (product of IGM Resins, intramolecular cleavage type)
Esacure One: Difunctional oligomeric alpha hydroxy ketone (product of IGM Resins, intramolecular cleavage type)
Omnirad MBF: Methyl benzoylformate (product of IGM Resins, intramolecular hydrogen removal type)
KBM-5103:3-Acryloxypropyl trimethoxysilane (product of Shin-Etsu Chemical Co., Ltd.)
UV-3300B: Urethane acrylate oligomer (weight average molecular weight: 13,000, product of Mitsubishi Chemical Co., Ltd.)
A-TMM-3: A mixture of pentaerythritol triacrylate (37 wt % based on 100 wt % of the total weight, molecular weight: 298) and pentaerythritol tetraacrylate (molecular weight: 352) (product of Shin-Nakamura Chemical Co., Ltd.)
V #1000: Dendrimer acrylate (molecular weight: 2,800, product of Osaka Organic Chemical Industry Co., Ltd.)
PE-590: Rosin ester (product of Arakawa Chemical Industry)
Polyvest110: Liquid polybutadiene (molecular weight 2,600, product of Evonik).

TABLE 2

| | | | Example | Example | Example | Example |
|---|---|---|---|---|---|---|
| | | | 1 | 2 | 3 | 4 |
| Composition | (Meth)acrylate | 4-HBA | 10 | 10 | 10 | 10 |
| | compound | IDAA | 20 | 21 | 30 | 29 |
| | | THF-A | 26 | 26 | 26 | 25 |
| | | IBXA | 30 | 29 | 20 | 19 |
| | Photopolymerization | Omnirad 819 | 0.9 | 2.2 | 0.9 | 0.9 |
| | initiator | Esacure One | | | | |
| | | Omnirad MBF | | | | 2.1 |
| | Silane coupling agent | KBM-5103 | 0.4 | 0.4 | 0.4 | 0.4 |
| | Urethane | UV-3300B | 4 | 1.9 | 4 | 3.9 |
| | (meth)acrylate | | | | | |
| | oligomer | | | | | |
| | (Meth)acrylate | D-1 | 9 | | | |
| | copolymer | D-2 | | 9 | | |
| | | D-3 | | | 9 | 9 |
| | | D-4 | | | | |
| | | D-5 | | | | |
| | | L-1 | | | | |
| | Multifunctional | A-TMM-3 | | | | |
| | methacrylate | V#1000 | | | | |
| | monomer | | | | | |
| | Rosin ester | PE-590 | | | | |
| | Liquid plasticizer | Polyvest110 | | | | |
| | Shear viscosity | 30° C. | 13 | 14 | 16 | 16 |
| Adhesive | 180° peel strength | 25° C. | 1800 | 2700 | 2000 | 2300 |
| member | (gf/25 mm) | | | | | |
| evaluation | 180° peel strength | 85° C., 85% RH | 390 | 340 | 200 | 320 |
| | (gf/25 mm) | | | | | |

Each of the resin compositions of Examples 1 to 4 includes one of (meth)acrylate copolymers D-1 to D-3. As described above, (meth)acrylate copolymers D-1 to D-3 correspond to dendritic (meth)acrylate copolymers having at least one (meth)acrylate group at at least one terminal, according to an embodiment. The resin compositions of Examples 1 to 4 further include at least one urethane (meth)acrylate having a weight average molecular weight of about 4,000 to about 50,000, and the weight of the urethane (meth)acrylate is about 1 wt % or more and about 20 wt % or less based on 100 wt % of the total weight of the resin composition.

Referring to the shear viscosity in Table 2, it can be found that the resin compositions of Examples 1 to 4 have a shear viscosity of about 50 mPa·s or less as measured at about 30° C. by the JISZ8803 method. The resin compositions of Examples 1 to 4 are resin compositions according to embodiments and include a monofunctional (meth)acrylate compound, a photopolymerization initiator, and a dendritic (meth)acrylate copolymer having at least one (meth)acrylate group at at least one terminal. Therefore, it can be found that the resin composition according to an embodiment exhibits excellent discharge properties.

Referring to the evaluation of the adhesive members in Table 2, it can be found that the adhesive members of Examples 1 to 4 after photocuring in the air have a 180° peel strength of about 1500 gf/25 mm or more against a glass substrate at about 25° C. In addition, it can be found that the adhesive members of Examples 1 to 4 after photocuring in the air have a 180° peel strength of about 200 gf/25 mm or more against a glass substrate under conditions of about 85° C. and about 85% relative humidity. The adhesive members of Examples 1 to 4 after photocuring in the air are formed from the resin compositions according to embodiments. Accordingly, it can be found that an adhesive member formed from a resin composition including a monofunctional (meth)acrylate compound, a photopolymerization initiator, and a dendritic (meth)acrylate copolymer having at least one (meth)acrylate group at at least one terminal exhibits excellent adhesive reliability at room temperature and at high temperature and high humidity.

TABLE 3

| | | | Comparative | Comparative | Comparative | Comparative | Comparative | Comparative |
|---|---|---|---|---|---|---|---|---|
| | | | Example | Example | Example | Example | Example | Example |
| | | | 5 | 6 | 7 | 8 | 9 | 10 |
| Composition | (Meth)acrylate | 4-HBA | 10 | 10 | 10 | 10 | 10 | 9 |
| | compound | IDAA | 21 | 30 | 29 | 29 | 21 | 37 |
| | | THF-A | 26 | 26 | 25 | 25 | 26 | 15 |
| | | IBXA | 29 | 20 | 20 | 20 | 29 | 28 |
| | Photopolymerization | Omnirad | 2.2 | 0.9 | 0.9 | 0.7 | 2.2 | 1.6 |
| | initiator | 819 | | | | | | |
| | | Esacure | | | | 3.8 | | |
| | | One | | | | | | |
| | | Omnirad | | | 1.9 | | | |
| | | MBF | | | | | | |
| | Silane coupling | KBM- | 0.4 | 0.4 | 0.4 | 0.4 | 0.4 | 0.4 |
| | agent | 5103 | | | | | | |
| | Urethane | UV-3300B | 1.9 | 4 | 3.9 | 1.9 | 1.9 | |
| | (meth)acrylate | | | | | | | |
| | oligomer | | | | | | | |
| | (Meth)acrylate | D-1 | | | | | | |
| | copolymer | D-2 | | | | | | |
| | | D-3 | | | | | | |
| | | D-4 | 9 | | | | | |
| | | D-5 | | 9 | 9 | | | |
| | | L-1 | | | | 9 | | |
| | Multifunctional | A-TMM-3 | | | | | 9 | |
| | methacrylate | V#1000 | | | | | | 9 |
| | monomer | | | | | | | |
| | Rosin ester | PE-590 | | | | | | |
| | Liquid | Polyvest110 | | | | | | |
| | plasticizer | | | | | | | |
| | Shear viscosity | 30° C. | 14 | 16 | 16 | 13 | 5 | 7 |
| Adhesive | 180° peel | 25° C. | 1100 | 1900 | 2300 | 300 | 320 | <50 |
| member | strength (gf/25 | | | | | | | |
| evaluation | mm) | | | | | | | |
| | 180° peel | 85° C., 85% | 170 | 90 | 140 | 440 | 10 | <50 |
| | strength (gf/25 | RH | | | | | | |
| | mm) | | | | | | | |

The resin compositions of Comparative Examples 5 to 7 include (meth)acrylate copolymers D-4 or D-5. As described above, (meth)acrylate copolymers D-4 and D-5 correspond to dendritic (meth)acrylate copolymers that do not contain a (meth)acrylate group at the terminal. The resin composition of Comparative Example 8 includes (meth)acrylate copolymer L-1. As described above, (meth)acrylate copolymer L-1 corresponds to a linear (meth)acrylate copolymer that contains a (meth)acrylate group at the terminal. The resin compositions of Comparative Examples 9 and 10 do not include a (meth)acrylate copolymer but include a multifunctional methacrylate monomer that contains a (meth)acrylate group at the terminal of a structure.

Referring to the evaluation of the adhesive members in Table 3, the adhesive member of Comparative Example 5 after photocuring in the air has a 180° peel strength of less than about 1500 gf/25 mm against a glass substrate at about 25° C. In addition, the adhesive members of Comparative Examples 5 to 7 after photocuring in the air have a 180° peel strength of less than about 200 gf/25 mm against a glass substrate under conditions of about 85° C. and about 85% relative humidity. It can be found that the adhesive members of Comparative Examples 5 to 7 after photocuring in the air exhibited a low 180° peel strength at room temperature and/or high temperature and high humidity, because the dendritic (meth)acrylate copolymers do not contain a (meth)acrylate group at the terminal.

The adhesive member of Comparative Example 8 after photocuring in the air has a 180° peel strength of less than about 1500 gf/25 mm against a glass substrate at about 25° C. In Comparative Example 8, it can be found that the adhesive member after photocuring in the air exhibited a low 180° peel strength at room temperature due to the inclusion of the linear (meth)acrylate copolymer having a (meth)acrylate group at the terminal.

In Comparative Examples 9 and 10, the adhesive members after photocuring in the air exhibited a 180° peel strength of less than about 1500 gf/25 mm against a glass substrate at about 25° C., and a 180° peel strength of less than about 200 gf/25 mm against a glass substrate under conditions of about 85° C. and about 85% relative humidity. In Comparative Examples 9 and 10, it can be found that the adhesive members after photocuring in the air did not include a (meth)acrylate copolymer but included a multifunctional methacrylate monomer having a (meth)acrylate group at the terminal of a structure, and thus exhibited a low 180° peel strength at room temperature and at high temperature and high humidity.

TABLE 4

| | | | Comparative | Comparative | Comparative | Comparative | Comparative | Comparative |
|---|---|---|---|---|---|---|---|---|
| | | | Example | Example | Example | Example | Example | Example |
| | | | 11 | 12 | 13 | 14 | 15 | 16 |
| Composition | (Meth)acrylate | 4-HBA | 12 | 9 | 10 | 10 | 7 | 3 |
| | compound | IDAA | 16 | 36 | 22 | 39 | 14 | 14 |
| | | THF-A | 36 | 14 | 27 | 16 | 19 | 5 |
| | | IBXA | 12 | 27 | 30 | 30 | 22 | 10 |
| | Photopolymerization | Omnirad | 2.1 | 1.8 | 1.3 | 1 | 1.3 | 1.8 |
| | initiator | 819 | | | | | | |
| | | Esacure | | | | | | |
| | | One | | | | | | |
| | | Omnirad | | | | | | |
| | | MBF | | | | | | |
| | Silane | KBM-5103 | 0.4 | 0.4 | 0.4 | 0.5 | 0.3 | 0.5 |
| | coupling | | | | | | | |
| | agent | | | | | | | |
| | Urethane | UV-3300B | | 12.4 | | 3.9 | 2.9 | 62 |
| | (meth)acrylate | | | | | | | |
| | oligomer | | | | | | | |
| | (Meth)acrylate | D-1 | | | | | 33 | |
| | copolymer | D-2 | | | | | | |
| | | D-3 | | | | | | |
| | | D-4 | | | | | | |
| | | D-5 | | | | | | |
| | | L-1 | | | | | | |
| | Multifunctional | A-TMM-3 | | | | | | |
| | methacrylate | V#1000 | | | | | | 3 |
| | monomer | | | | | | | |
| | Rosin ester | PE-590 | 22 | | 5 | | | |
| | Liquid | Polyvest110 | | | 5 | | | |
| | plasticizer | | | | | | | |
| | Shear | 30° C. | 8 | 18 | 7 | 6 | 184 | 70 |
| | viscosity | | | | | | | |
| Adhesive | 180° peel | 25° C. | 2200 | <50 | <50 | 1100 | <50 | — |
| member | strength | | | | | | | |
| evaluation | (gf/25 mm) | | | | | | | |
| | 180° peel | 85° C., 85% | 80 | <50 | <50 | 50 | <50 | — |
| | strength | RH | | | | | | |
| | (gf/25 mm) | | | | | | | |

The resin composition of Comparative Example 11 does not contain a (meth)acrylate copolymer but includes a rosin ester. The resin compositions of Comparative Examples 12 and 14 do not contain a (meth)acrylate copolymer. The resin composition of Comparative Example 13 does not include a (meth)acrylate copolymer but includes a rosin ester and polybutadiene as a liquid plasticizer. The resin composition of Comparative Example 15 includes a dendritic (meth)acrylate copolymer having at least one (meth)acrylate group at the terminal but has a shear viscosity measured at about 30° C. of greater than about 50 mPa·s. The resin composition of Comparative Example 16 does not include a (meth)acrylate copolymer but includes a multifunctional methacrylate monomer having a (meth)acrylate group at the terminal of a structure.

Referring to the evaluation of the adhesive members in Table 4, the adhesive member of Comparative Example 11 after photocuring in the air has a 180° peel strength of less than about 200 gf/25 mm with respect to a glass substrate under conditions of about 85° C. and about 85% relative humidity. The adhesive members of Comparative Examples 12 to 15 after photocuring in the air have a 180° peel strength of less than about 1500 gf/25 mm with respect to a glass substrate at about 25° C., and a 180° peel strength of less than about 200 gf/25 mm with respect to a glass substrate under conditions of about 85° C. and about 85% relative humidity. The adhesive member of Comparative Example 16 after photocuring in the air cannot perform inkjet discharging, and therefore, the measurement of the 180° peel strength was impossible.

It can be found that, in Comparative Example 11, the adhesive member after photocuring in the air did not include a (meth)acrylate copolymer but included a rosin ester, and thus, exhibited a low 180° peel strength at high temperature and high humidity. In Comparative Examples 12 and 14, the adhesive members after photocuring in the air did not include a (meth)acrylate copolymer, in Comparative Example 13, the adhesive member after photocuring in the air did not include a (meth)acrylate copolymer but included a rosin ester and polybutadiene as a liquid plasticizer, and in Comparative Example 15, the adhesive member after photocuring in the air included a dendritic (meth)acrylate copolymer having at least one (meth)acrylate group at the terminal but included a resin composition having a shear viscosity of greater than about 50 mPa·s measured at about 30° C., and thus exhibited a low 180° peel strength at room temperature and at high temperature and high humidity. In Comparative Example 16, the adhesive member after photocuring in the air did not include a (meth)acrylate copolymer but included a multifunctional methacrylate monomer having a (meth)acrylate group at the terminal of a structure and included a resin composition having a shear viscosity of greater than about 50 mPa·s measured at about 30° C., and thus, inkjet discharge was impossible.

The electronic apparatus according to an embodiment may include an adhesive member disposed between a display module and a window. The electronic apparatus according to an embodiment may be manufactured using a method for manufacturing an electronic apparatus according to an embodiment. The electronic apparatus according to an embodiment may include a step of providing a resin composition to form the adhesive member. The resin composition according to an embodiment may include a monofunctional (meth)acrylate compound, a photopolymerization initiator, and a dendritic (meth)acrylate copolymer having at least one (meth)acrylate group at at least one terminal. In addition, the resin composition of an embodiment may have a shear viscosity of about 50 mPa·s or less as measured by the JISZ8803 method at about 30° C. Accordingly, the resin composition of an embodiment may be cured in the air in a short time, exhibit excellent discharge properties, and exhibit excellent adhesive strength at room temperature and at high temperature and high humidity after curing. The electronic apparatus of an embodiment including the adhesive member formed by curing the resin composition may exhibit excellent reliability.

The resin composition of an embodiment includes a dendritic (meth)acrylate copolymer having at least one (meth)acrylate group at at least one terminal and may be cured in a short time in the air, exhibit excellent discharge properties, and exhibit high adhesive properties at room temperature and at high temperature and humidity after curing.

The method for manufacturing an electronic apparatus of an embodiment may exhibit excellent processability by including a step of providing the resin composition of an embodiment and forming an adhesive member.

The electronic apparatus of an embodiment may exhibit excellent reliability by including an adhesive member including a polymer obtained from the resin composition of an embodiment.

In the above, description has been made with reference to embodiments of the present disclosure, but those skilled or of ordinary skill in the art may understand that various modifications and changes may be made to the present disclosure insofar as such modifications and changes do not depart from the spirit and technical scope of the present disclosure set forth in the claims to be described later.

Therefore, the technical scope of the present disclosure is not to be limited to the contents stated in the detailed description of the specification, but should be determined by the claims.

What is claimed is:

1. A resin composition comprising:
at least one monofunctional (meth)acrylate compound;
at least one photopolymerization initiator; and
a dendritic (meth)acrylate copolymer having at least one (meth)acrylate group at at least one terminal,
wherein a shear viscosity is about 50 mPa·s or less as measured by a JISZ8803 method at about 30° C.

2. The resin composition of claim 1, wherein a weight average molecular weight of the dendritic (meth)acrylate copolymer is about 3,000 or more.

3. The resin composition of claim 1, wherein the dendritic (meth)acrylate copolymer is synthesized with a (meth)acrylate monomer and a radical polymerization initiator.

4. The resin composition of claim 3, wherein the (meth)acrylate monomer comprises at least one of methyl methacrylate (MMA) and isobornyl methacrylate (IBXMA).

5. The resin composition of claim 1, wherein
the resin composition further comprises at least one urethane (meth)acrylate having a weight average molecular weight of about 4,000 or more and about 50,000 or less, and
the urethane (meth)acrylate is present in an amount of about 1 wt % or more and about 20 wt % or less based on 100 wt % of a total weight of the resin composition.

6. The resin composition of claim 1, wherein, after photocuring in air, a 180° peel strength against a glass substrate at about 25° C. is about 1500 gf/25 mm or more.

7. The resin composition of claim 1, wherein, after photocuring in air, a 180° peel strength against a glass substrate under conditions of about 85° C. and about 85% relative humidity is about 200 gf/25 mm or more.

8. The resin composition of claim 1, wherein the resin composition is provided by an inkjet printing method or a dispensing method.

9. A method for manufacturing an electronic apparatus, the method comprising:
preparing a display module;
providing a window on the display module; and
providing an adhesive member on the display module or the window prior to the providing of the window,
wherein the providing the adhesive member comprises:
providing a resin composition having a shear viscosity of about 50 mPa·s or less as measured by a JISZ8803 method at about 30° C. on the display module or the window; and
irradiating the provided resin composition with light in air to form the adhesive member,
wherein the resin composition comprises at least one monofunctional (meth)acrylate compound, at least one photopolymerization initiator, and a dendritic (meth)acrylate copolymer having at least one (meth)acrylate group at at least one terminal, and
wherein the light comprises UVA and UVV and has an accumulated illuminance of about 900 mW and an accumulated light quantity of about 1800 mJ/cm².

10. The method for manufacturing an electronic apparatus of claim 9, wherein the adhesive member has a 180° peel strength of about 1500 gf/25 mm or more against a glass substrate at about 25° C.

11. The method for manufacturing an electronic apparatus of claim 9, wherein the adhesive member has a 180° peel strength of about 200 gf/25 mm or more against a glass substrate under conditions of about 85° C. and about 85% relative humidity.

12. The method for manufacturing an electronic apparatus of claim 9, wherein a weight average molecular weight of the dendritic (meth)acrylate copolymer is about 3,000 or more.

13. The method for manufacturing an electronic apparatus of claim 9, wherein the dendritic (meth)acrylate copolymer is synthesized with a (meth)acrylate monomer and a radical polymerization initiator.

14. The method for manufacturing an electronic apparatus of claim 9, wherein the resin composition further comprises at least one urethane (meth)acrylate having a weight average molecular weight of about 4,000 or more and about 50,000 or less, and
wherein the urethane (meth)acrylate is present in an amount of about 1 wt % or more and about 20 wt % or less based on 100 wt % of a total weight of the resin composition.

15. An electronic apparatus comprising:
a display module;
a window disposed on the display module; and
an adhesive member disposed between the display module and the window,
wherein the adhesive member comprises a polymer obtained from a resin composition comprising at least one monofunctional (meth)acrylate compound, at least one photopolymerization initiator, and a dendritic (meth)acrylate copolymer having at least one (meth)acrylate group at at least one terminal, and
wherein the resin composition has a shear viscosity of about 50 mPa·s or less as measured by a JISZ8803 method at about 30° C.

16. The electronic apparatus of claim 15, wherein the adhesive member has a 180° peel strength of about 1500 gf/25 mm or more against a glass substrate at about 25° C.

17. The electronic apparatus of claim 15, wherein the adhesive member has a 180° peel strength of about 200 gf/25 mm or more against a glass substrate under conditions of about 85° C. and about 85% relative humidity.

18. The electronic apparatus of claim 15, further comprising a light control layer disposed between the adhesive member and the window and an optical adhesive layer disposed between the light control layer and the window, wherein the optical adhesive layer comprises the polymer obtained from the resin composition.

19. The electronic apparatus of claim 15, wherein the display module further comprises a display panel and an input detection part disposed between the display panel and the window,
wherein the adhesive member is disposed between the display panel and the input detection part or between the input detection part and the window.

20. The electronic apparatus of claim 15, further comprising at least one of a processor, a memory and a power module.
